(19) United States
(12) Patent Application Publication
(10) Pub. No.: US 2019/0097363 A1
(43) Pub. Date: Mar. 28, 2019

(54) PROTECTION CONTACTOR

(71) Applicant: MODA-INNOCHIPS CO., LTD., Ansan-Si, Gyeonggi-Do (KR)

(72) Inventors: Seung Hun CHO, Siheung-Si, Gyeonggi-Do (KR); Sung Jin HEO, Ansan-si, Gyeonggi-do (KR); Dong Suk LEE, Incheon (KR)

(21) Appl. No.: 16/097,170

(22) PCT Filed: May 25, 2017
(86) PCT No.: PCT/KR2017/005484

§ 371 Date: Oct. 26, 2018

(30) Foreign Application Priority Data
May 26, 2016 (KR) 10-2016-0064888

(51) Int. Cl. H01R 13/66; H01G 4/40; H01R 12/71; H01R 13/24; H05K 1/18; H05K 1/02; H05K 9/00

(52) U.S. Cl. CPC H01R 13/6666; H01G 4/40; H01R 12/714; H01R 13/24; H05K 1/181; H05K 1/0259; H05K 2201/10196; H05K 2201/10015; H05K 2201/1031; H05K 2201/10515; H05K 2201/1053; H05K 2201/10962; H05K 9/0067

(57) ABSTRACT

A protection contactor includes a contact part coming into contact with a conductor of an electric device and having elasticity and an ESD protection part connected to a portion of the contact part to extend to a circuit board disposed to be spaced apart from the contact part and comprising a conductive material. Thus, in accordance with the exemplary embodiments, current due to an overvoltage or an ESD voltage of a discharge starting voltage concentratedly flows through the protrusion to improve bypassing efficiency to a ground part. Thus, the current due to the overvoltage or the ESD voltage that is above the discharge starting voltage may be effectively bypassed to prevent an internal circuit from being damaged by static electricity.

### TECHNICAL FIELD

The present disclosure relates to a protection contactor, and more particularly, to a protection contactor that is capable of preventing a user from being electrically shocked by leakage current due to power introduced from the outside.

### BACKGROUND

Various components are integrated into electronic devices having multifunction such as smartphones according to their functions. Also, electronic devices are provided with antennas capable of receiving various frequency bands such as a wireless LAN (wireless LAN), a Bluetooth (Bluetooth), and a GPS (Global Positioning System). A portion of the antennas may be provided as a built-in antenna and installed in a case constituting each of the electronic devices. Thus, a contactor for electrically connecting the antenna installed in the case to a built-in circuit board of the electronic device is installed.

In recent years, with an increased emphasis on the elegant image and durability of the electronic device, the supply of a terminal including a case made of a metal material is increasing. That is, the supply of a smartphone of which a border is made of a metal, or the rest case except for a front image display part is made of a metal is increasing.

However, when the case is made of the metal material, static electricity having a high voltage may be momentarily introduced through the external metal case, and then, the static electricity may be introduced into an internal circuit through the contactor to damage the circuit.

Also, when a charger in which an overcurrent protection circuit is not installed is used in the electronic device including the metal case, an electric shock accident may occur when a smartphone is used during the charging. That is, when a non-genuine charger or a defective charger is used to charge the smartphone, it may be moved along the ground of the internal circuit and transmitted to the case coming into contact with a user. Thus, when the user comes into contact with the case during the charging of the electronic device, the electric shock accident of the user may occur.

Accordingly, when it is intended to provide the contactor for electrically connecting the case to the internal circuit, it is necessary to provide a contactor that is capable of preventing the internal circuit from being damaged and preventing the user from being electrically shocked.

### PRIOR ART DOCUMENT

### Patent Document

(Patent Document 1) Korean Patent Registration No. 10-0809249.

### DISCLOSURE OF THE INVENTION

### Technical Problem

The present disclosure provide a protection contactor that is capable of preventing a user from being electrically shocked by leakage current due to power introduced from the outside and protecting an internal circuit against the leakage current due to static electricity.

The present disclosure also provides a protection contactor that is capable of transmitting a communication signal introduced from the outside while minimizing attenuation of the communication signal.

### Technical Solution

In accordance with an exemplary embodiment, a protection contactor includes: a contact part coming into contact with a conductor of an electric device and having elasticity; and an ESD protection part connected to a portion of the contact part to extend to a circuit board disposed to be spaced apart from the contact part and including a conductive material.

The ESD protection part may be disposed to correspond to a ground part of the circuit board.

The ESD protection part may be disposed between a bottom surface of the contact part and a top surface of the circuit board or disposed at a side of the contact part.

The protection contactor may further include a discharge member connected to the contact part and the circuit board and including an ESD protection material.

The ESD protection part may include an auxiliary member disposed below the protrusion to face the protrusion and to be spaced apart from the protrusion and including a conductive material.

The ESD protection part may include a block in which at least the protrusion is accommodated.

The block may have an empty space therein.

The block may include an ESD protection material.

The protection contactor may further include a coating film, to which the ESD protection material is applied, on an outer circumferential surface of the block.

The protection contactor may further include a laminate disposed between the conductor and the circuit board and formed by at least one ceramic sheet.

The protection contactor may further include a capacitor part, wherein the capacitor part may include: first and second external electrodes, which are respectively disposed on an outer surface of the laminate facing the conductor and an outer surface of the laminate facing the circuit board; and a plurality of internal electrodes extending to cross the first and second external electrodes in the laminate and arranged to be alternately connected to the first and second external electrodes.

The laminate may be disposed at a side of the ESD protection part and spaced apart from or connected to the ESD protection part, and the protection contactor may further include a coupling part configured to couple the laminate and the ESD protection part to the contact part and including the conductive material.

The coupling part may be applied to a lower portion of the contact part as a conductive bonding agent, and the laminate and the ESD protection part may be bonded to the contact part by using the conductive bonding agent.

The coupling part may be coupled to the laminate and the contact part and include a coupling member configured to mechanically couple the laminate and the ESD protection part to the contact part.

In accordance with another exemplary embodiment, a protection contactor includes: a contact part coming into contact with a conductor of an electric device and having elasticity; an electric shock protection part including an ESD protection part connected to a portion of the contact part to extend to a circuit board disposed to be spaced apart from the contact part and including a conductive material; and a coupling part connected to the contact part, configured to grip at least a portion of the electric shock protection part to be coupled to the contact part, and including a conductive material.

The electric shock protection part may include a capacitor part disposed between the contact part and a circuit board disposed to be spaced apart from the contact part and having at least a side connected to the circuit board.

A configuration of the electric shock protection part may include a first area extending in a first direction and a second area extending in the first direction to correspond to the first area and disposed below the first area, a length of the first area in a second direction crossing the first direction may be greater than that of the second area in the second direction so that both edges of the first area in the second direction have protrusion areas protruding from the second area, at least one of the capacitor part and the ESD protection part may be disposed on each of the first and second areas, and the coupling part may be coupled to the protrusion area disposed on the first area.

The capacitor part and the ESD protection part may be disposed on each of the first and second areas, and the capacitor part may be disposed on a side of the ESD protection part, and the ESD protection part and the capacitor part may be disposed to be arranged in the first direction.

The coupling part may grip at least one of the capacitor part and the ESD protection part, which are disposed on the protrusion area of the first area, of the capacitor part and the ESD protection part, which are disposed on the first area.

The capacitor part may be provided in a pair, the pair of capacitor parts may be disposed to be spaced apart from each other in the first direction, and the ESD protection part may be disposed between the pair of capacitor parts.

The pair of capacitor parts and the protrusion may be spaced apart from each other, and the protrusion of the ESD protection part may be integrally connected to a lower portion of the coupling part to correspond to a spaced space between the pair of capacitor parts.

The capacitor part may be disposed on each of the first and second areas, the protrusion may be disposed on a side of the capacitor in the first direction and have an upper end connected to the coupling part and one surface coming into contact with the capacitor, and the coupling part may grip an area of at least the capacitor part, which corresponds to the protrusion area of the first area.

The protrusion may be integrally connected to an end of the coupling part in the first direction.

The ESD protection part may be disposed on the first area, and the capacitor part may be disposed on the second area.

The electric shock protection part may include a support part disposed on a side of the ESD protection part on the first area, and the coupling part may grip at least one of areas of the ESD protection part and the support part, which correspond to the protrusion area of the first area.

The capacitor part may include a connection electrode having one end connected to the ESD protection part and the other end connected to the circuit board.

A plating layer may be disposed on at least one of an outer surface of the electric shock protection part and an outer surface of the circuit board.

In accordance with yet another exemplary embodiment, a protection contactor includes: a contact part coming into contact with a conductor of an electric device and having elasticity; a capacitor part disposed between the contact part and a circuit board disposed to be spaced apart from the contact part and having at least a side connected to the circuit board; and an ESD protection part disposed between the contact part and the circuit board and having at least a side connected to the contact part.

The capacitor part may include a capacitor including internal electrodes facing each other, and each of the capacitors may not overlap the ESD protection part.

The capacitor part and the ESD protection part may be disposed at the same height.

The capacitor part may include a plurality of capacitors respectively disposed on one side and the other side of the ESD protection part, at least one ESD protection part may be disposed between the plurality of capacitor parts, and the plurality of capacitor parts and the ESD protection part may be disposed on the same plane.

The capacitor part and the ESD protection part may be disposed at heights different from each other.

The capacitor part may be disposed below the ESD protection part, and a position of the capacitor disposed in the capacitor part may be different from that of the ESD protection part in a width direction.

The capacitor parts may include a plurality of capacitor parts respectively disposed on one side and the other side of the ESD protection part, and at least one ESD protection part may be disposed between the plurality of capacitor parts.

The ESD protection part may be disposed on one side above the capacitor part, and the capacitor of the capacitor part may be disposed on the other side.

The ESD protection part may include a protrusion connected to a portion of the contact part, extending to the circuit board disposed to be spaced apart from the contact part, and including a conductive material.

The ESD protection part may include a block in which the protrusion is accommodated therein.

The ESD protection part may be disposed to face a lower side of the protrusion and to be spaced apart from the protrusion and including a conductive material.

### Advantageous Effects

Provided is a protection contactor. The protection contactor includes a contact part coming into contact with a conductor of an electric device and having elasticity and an ESD protection part connected to a portion of the contact part to extend to a circuit board disposed to be spaced apart from the contact part and comprising a conductive material. Thus, in accordance with the exemplary embodiments, current due to an overvoltage or an ESD voltage of a discharge starting voltage concentratedly flows through the protrusion to improve bypassing efficiency to a ground part. Thus, the current due to the overvoltage or the ESD voltage that is above the discharge starting voltage may be effectively bypassed to prevent an internal circuit from being damaged by static electricity.

### BRIEF DESCRIPTION OF THE DRAWINGS

Exemplary embodiments can be understood in more detail from the following description taken in conjunction with the accompanying drawings, in which:

FIG. 1 is a view of an electronic device to which a protection contactor is applied in accordance with a first exemplary embodiment,

FIG. 2 is a view illustrating a first modified example of the electronic device to which the protection contactor is applied in accordance with the first exemplary embodiment,

FIG. 3 is a view illustrating a second modified example of the electronic device to which the protection contactor is applied in accordance with the first exemplary embodiment,

FIG. 4 is a view of an electronic device to which a protection contactor is applied in accordance with a second exemplary embodiment,

(a)-(f) of FIG. 5 are a views for explaining concept of an ESD protection part in, accordance with the first and second exemplary embodiments,

FIGS. 6 to 8 are views illustrating first to third modified examples of the electronic device to which the protection contactor is applied in accordance with the second exemplary embodiment,

FIGS. 9 to 12 are views illustrating third to sixth modified examples of the electronic device to which the protection contactor is applied in accordance with the first exemplary embodiment,

FIG. 13 is a view of an electronic device to which a protection contactor is applied in accordance with a third exemplary embodiment,

(a) of FIG. 14 is a view of an electronic device to which a protection contactor is applied in accordance with a fourth exemplary embodiment, and (b) of FIG. 14 is a view illustrating a state in which an ESD protection part is seen in a lateral direction of a contact part, a coupling part, and a capacitor part so as to conceptually explain a shape and formed position of an ESD protection part in (a) of FIG. 14,

(a) of FIG. 15 is a view illustrating a first modified example of the electronic device to which the protection contactor is applied in accordance with the fourth exemplary embodiment,

(b) of FIG. 15 is a view illustrating a state in which the ESD protection part is seen in the lateral direction of the contact part, the coupling part, and the capacitor part so as to conceptually explain the shape and formed position of the ESD protection part in (a) of FIG. 15,

(a) of FIG. 16 is a view illustrating a second modified example of the electronic device to which the protection contactor is applied in accordance with the fourth exemplary embodiment,

(b), (c) of FIG. 16 is a view illustrating a state in which the ESD protection part is seen in the lateral direction of the contact part, the coupling part, and the capacitor part so as to conceptually explain the shape and formed position of the ESD protection part in (a) of FIG. 16,

FIGS. 17 to 20 are views of an electronic device to which a protection contactor is applied in accordance with a fifth exemplary embodiment,

FIGS. 21 to 23 are views of an electronic device to which a protection contactor is applied in accordance with a sixth exemplary embodiment,

FIGS. 24 to 26 are views illustrating a modified example of the electronic device to which the protection contactor is applied in accordance with the sixth exemplary embodiment,

FIGS. 27 to 29 are views of an electronic device to which a protection contactor is applied in accordance with a seventh exemplary embodiment, and

FIG. 30 is a view illustrating a modified example of the electronic device to which the protection contactor is applied in accordance with the seventh exemplary embodiment.

### DETAILED DESCRIPTION OF EMBODIMENTS

Hereinafter, embodiments of the present invention will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

A protection contactor in accordance with exemplary embodiments may prevent a user from being electrically shocked by leakage current due to power introduced from the outside and protect an internal circuit against the leakage current due to the static electricity. Also, the present disclosure may provide a protection contactor that is capable of transmitting a signal while minimizing attenuation of the signal.

More particularly, the protection contactor may include an electric shock protection contactor that is applied to mobile electronic devices such as smartphones, tablet PCs, laptop PCs, DMBs, and cameras. Also, the electric shock protection contactor in accordance with exemplary embodiments may be disposed between a case constituting the electronic device and a circuit board including an internal circuit and have elasticity to reduce transfer of external force to the circuit board.

The electronic device largely includes a case 10 defining an overall outer appearance thereof and receiving an external signal as occasion demands, a circuit board installed in the case 10 and including an internal circuit that is capable of performing various functions for the electronic device, and a protection contactor disposed between the case 10 and the circuit board 20.

Here, the case 10 is made of a conductive material such as a metal to realize an elegant appearance and serve as an antenna. The case 10 made of the conductive material may be called a “conductor” of the electronic device.

Hereinafter, a protection contactor in accordance with exemplary embodiments will be described with reference to the accompanying drawings.

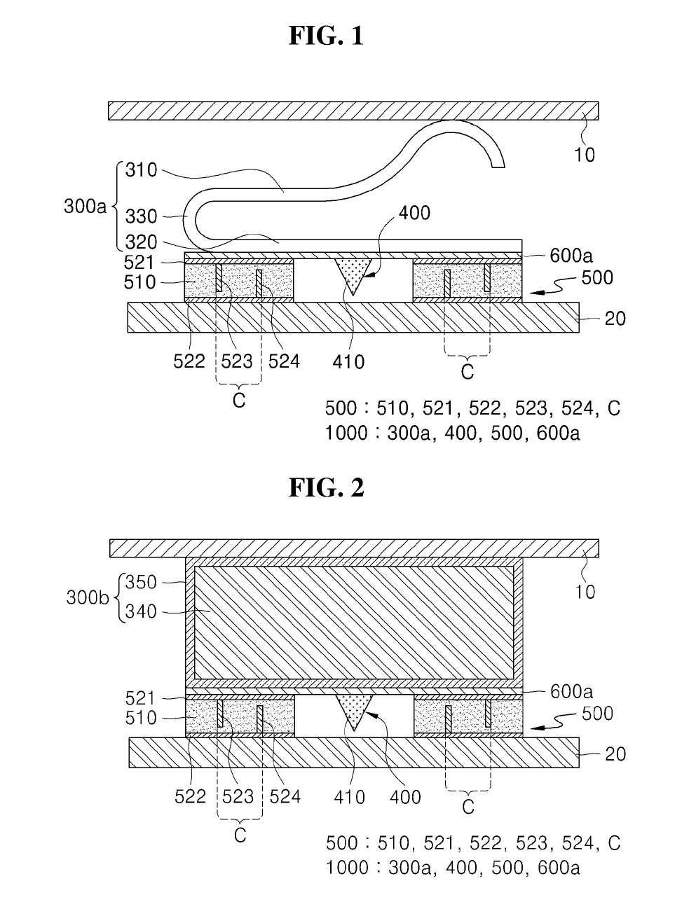

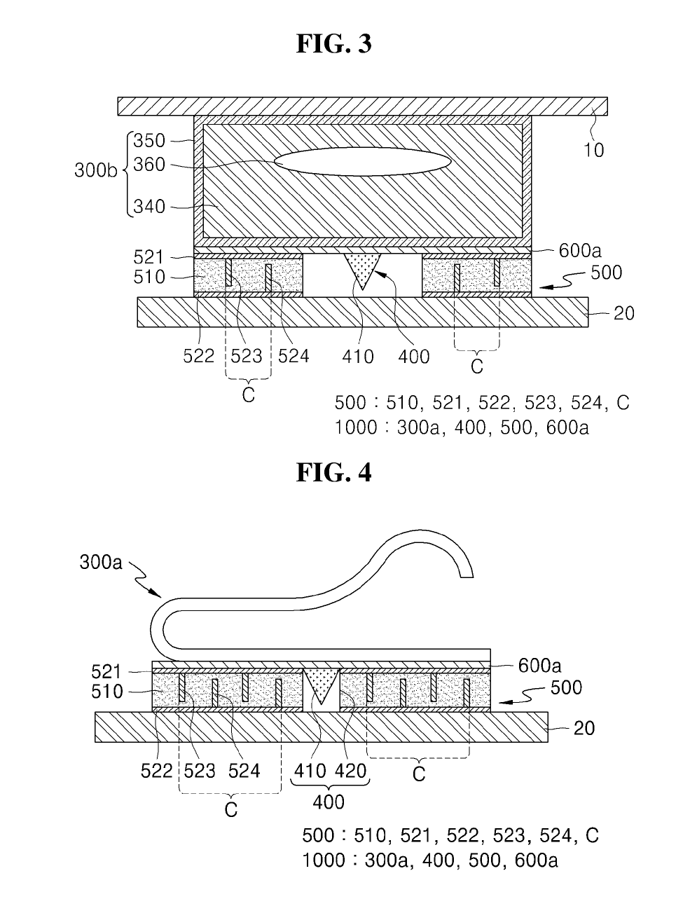

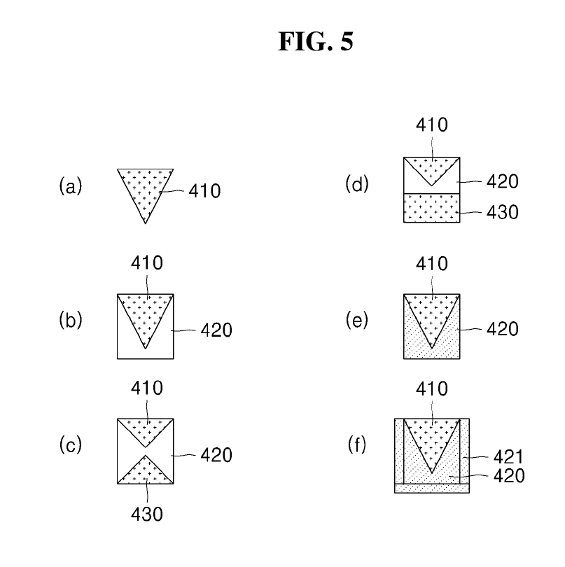

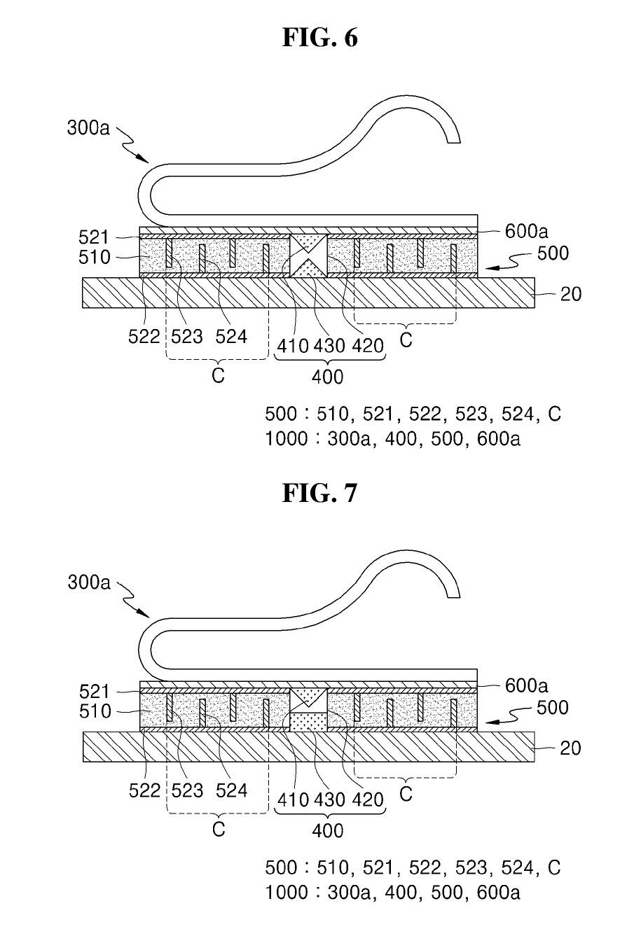

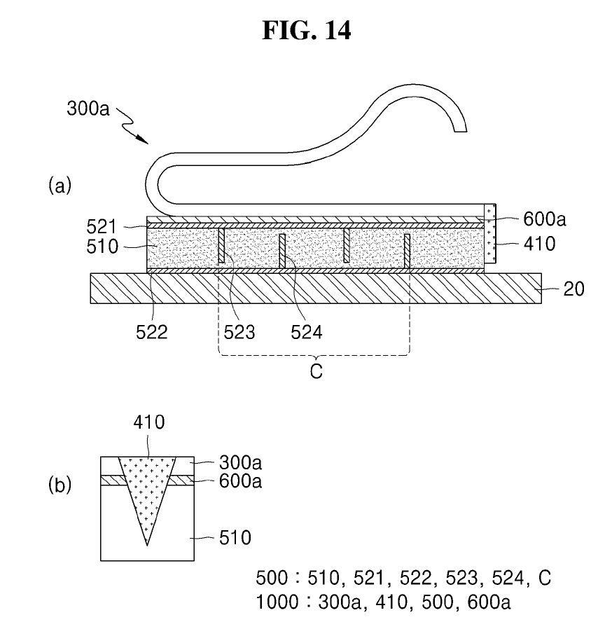

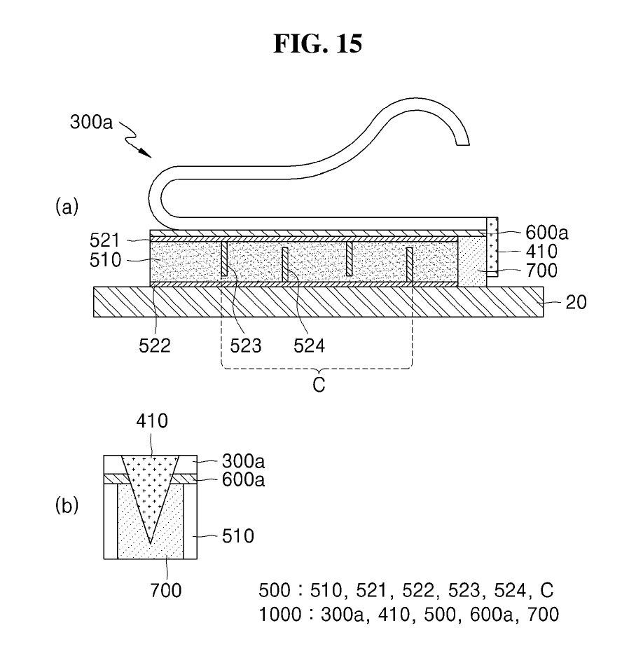

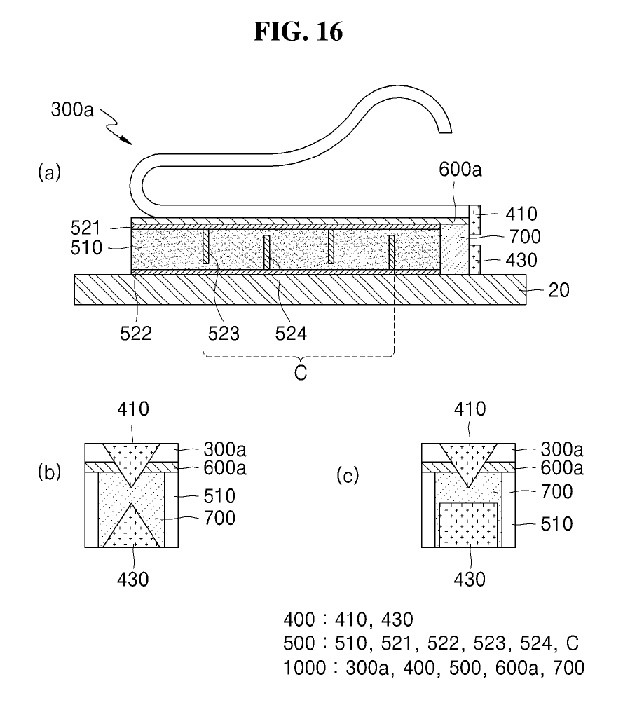

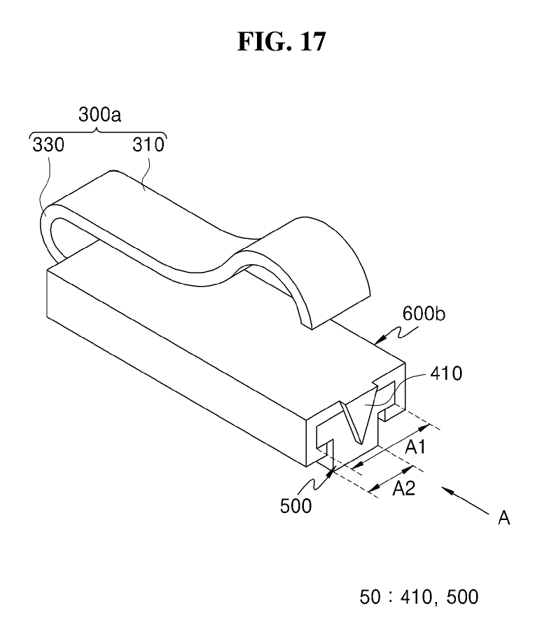

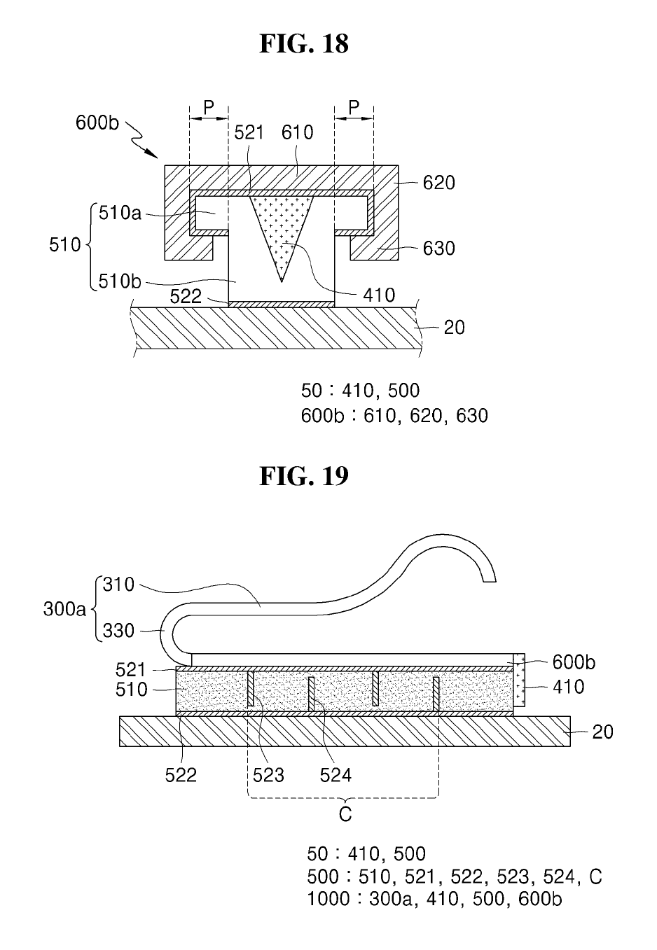

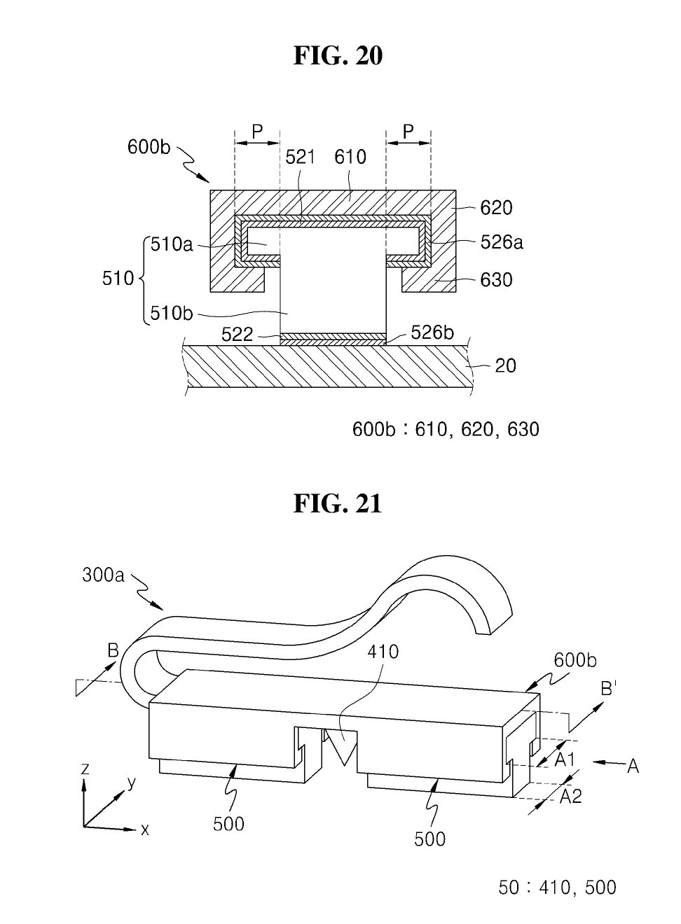

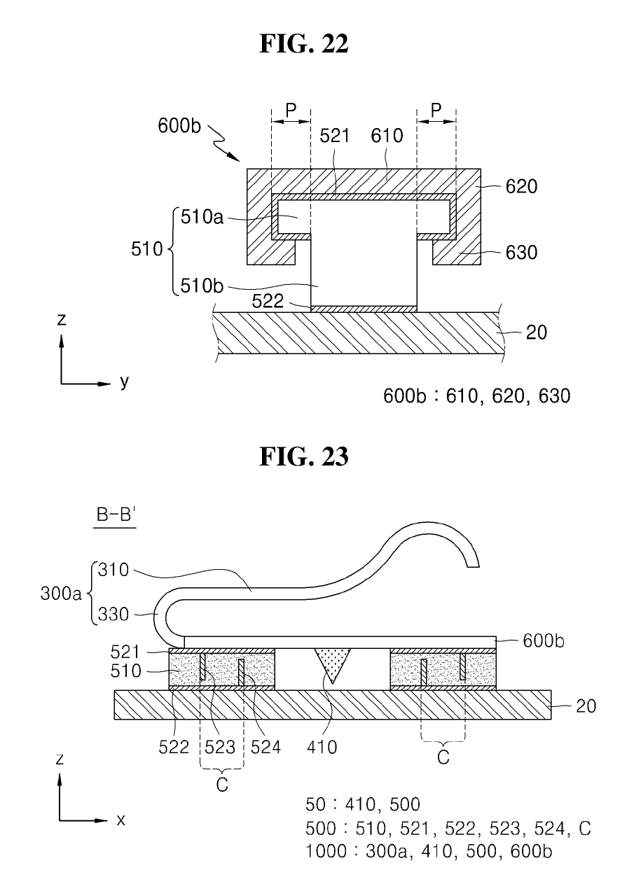

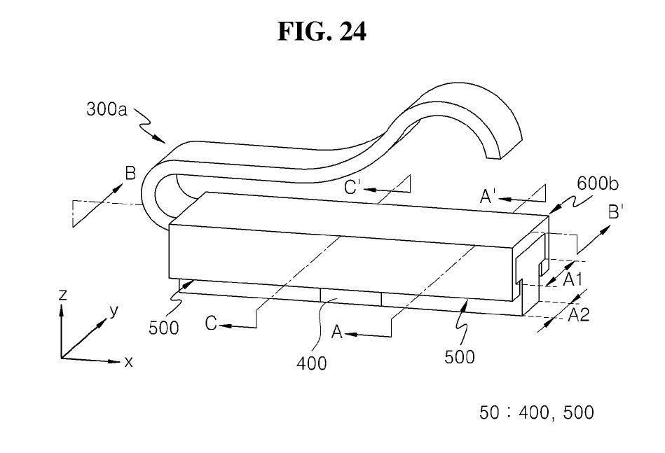

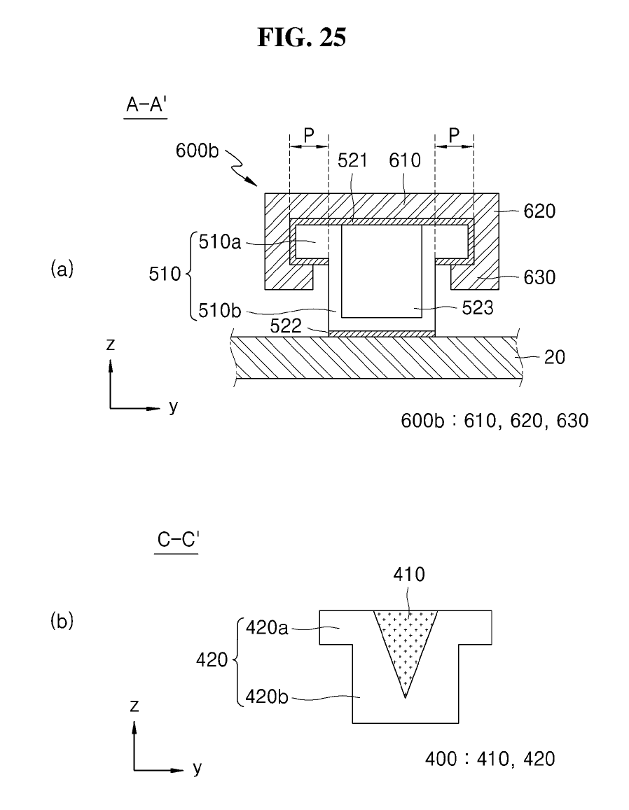

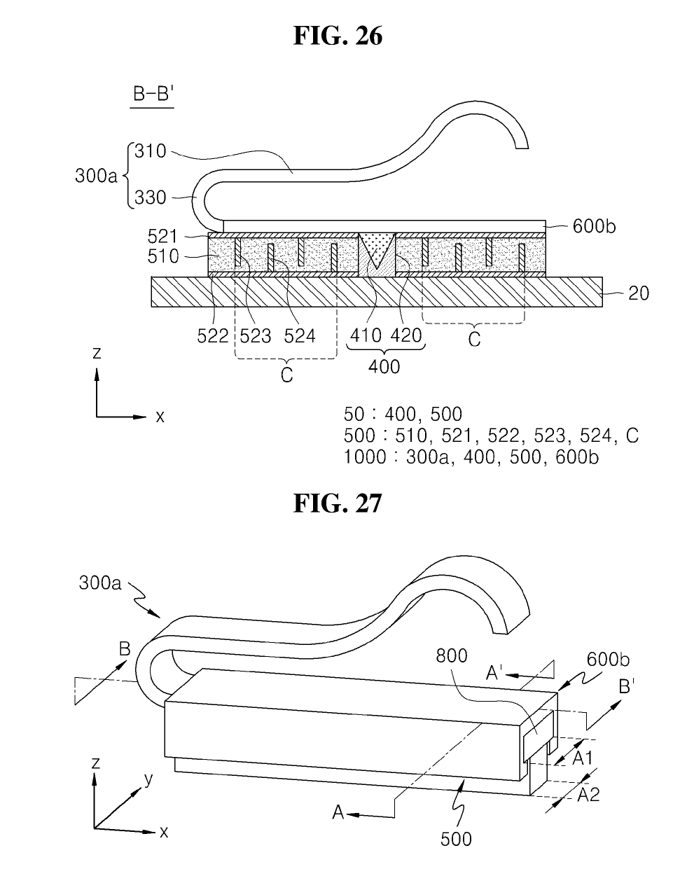

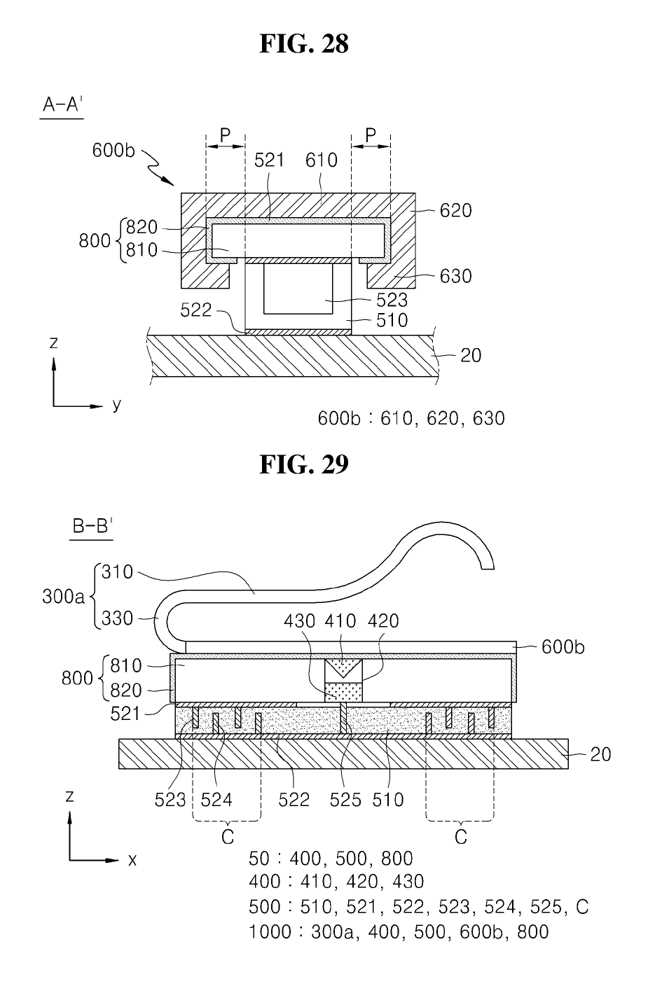

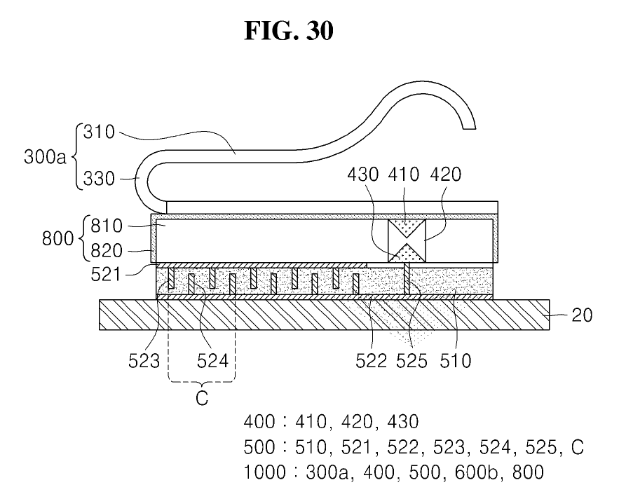

FIG. 1 is a view of an electronic device to which a protection contactor is applied in accordance with a first exemplary embodiment. FIG. 2 is a view illustrating a first modified example of the electronic device to which the protection contactor is applied in accordance with the first exemplary embodiment. FIG. 3 is a view illustrating a second modified example of the electronic device to which the protection contactor is applied in accordance with the first exemplary embodiment. FIG. 4 is a view of an electronic device to which a protection contactor is applied in accordance with a second exemplary embodiment. FIG. 5 is a view for explaining concept of an ESD protection part in accordance with the first and second exemplary embodiments. FIGS. 6 to 8 are views illustrating first to third modified examples of the electronic device to which the protection contactor is applied in accordance with the second exemplary embodiment. FIGS. 9 to 12 are views illustrating third to sixth modified examples of the electronic device to which the protection contactor is applied in accordance with the first exemplary embodiment. FIG. 13 is a view of an electronic device to which a protection contactor is applied in accordance with a third exemplary embodiment. (a) of FIG. 14 is a view of an electronic device to which a protection contactor is applied in accordance with a fourth exemplary embodiment, and (b) of FIG. 14 is a view illustrating a state in which an ESD protection part is seen in a lateral direction of a contact part, a coupling part, and a capacitor part so as to conceptually explain a shape and formed position of an ESD protection part in (a) of FIG. 14. (a) of FIG. 15 is a view illustrating a first modified example of the electronic device to which the protection contactor is applied in accordance with the fourth exemplary embodiment, and (b) of FIG. 15 is a view illustrating a state in which the ESD protection part is seen in the lateral direction of the contact part, the coupling part, and the capacitor part so as to conceptually explain the shape and formed position of the ESD protection part in (a) of FIG. 15. (a) of FIG. 16 is a view illustrating a second modified example of the electronic device to which the protection contactor is applied in accordance with the fourth exemplary embodiment, and (b) of FIG. 16 is a view illustrating a state in which the ESD protection part is seen in the lateral direction of the contact part, the coupling part, and the capacitor part so as to conceptually explain the shape and formed position of the ESD protection part in (a) of FIG. 16. FIGS. 17 to 20 are views of an electronic device to which a protection contactor is applied in accordance with a fifth exemplary embodiment. FIGS. 21 to 23 are views of an electronic device to which a protection contactor is applied in accordance with a sixth exemplary embodiment. FIGS. 24 to 26 are views illustrating a modified example of the electronic device to which the protection contactor is applied in accordance with the sixth exemplary embodiment. FIGS. 27 to 29 are views of an electronic device to which a protection contactor is applied in accordance with a seventh exemplary embodiment. FIG. 30 is a view illustrating a modified example of the electronic device to which the protection contactor is applied in accordance with the seventh exemplary embodiment.

As illustrated in FIG. 1, a protection contactor 1000 in accordance with a first exemplary embodiment includes a contact part 300a coming into electrical contact with a case 10 of the electronic device and having elasticity and an ESD protection part 400 electrically connected to the contact part 300a to extend from the contact part 300a to an circuit board 20, spaced apart from the circuit board 20 of the electronic device, and including a protrusion 410 made of a conductive material. Also, the protection contactor 1000 includes a coupling part 600a mutually bonding or coupling the contact part 300a to the ESD protection part 400 and a capacitor part 500 disposed between the contact part 300a and the circuit board 20.

The contact part 300a may have the elasticity to reduce an impact when external force is applied from the outside of the electronic device and be made of a material including the conductive material. As illustrated in FIG. 1, the contact part 300a may have a clip shape. More particularly, the contact part 300a includes a first extension 300a, which is disposed to face the case 10 and of which at least a portion comes into contact with the case 10, a second extension 320 electrically connected to the ESD protection part 400, and a third extension 330 extending to connect the first extension 310 to the second extension 320 and having elasticity.

The contact part 300a having the clip shape may be made of a material including a metal material such as copper (Cu).

Here, the first extension 310 may be connected to the third extension 330 to extend from the third extension 330 in one direction. Also, a portion of the first extension 310 may extend to be inclined, for example, inclined upward to the case 10 to come into contact with the case 10. Also, an area adjacent to the other end of the first extension 310 may have a shape with a convex curvature in a direction in which the case 10 is disposed. In other words, a peripheral area of an area of the first extension 310, which is farther away from the third extension 330 or includes the other end of the first extension, may have a shape with a bent portion that is bent upward. Here, the bent portion may come into contact with the case 10.

The second extension 320 may extend in parallel to the coupling part 600a from a top surface of the coupling part 600a and be coupled or bonded to the top surface of the coupling part 600a.

The third extension 330 may extend to connect the first extension 310 to the second extension 320. Also, the third extension 330 may extend at a predetermined curvature. The third extension 330 may be pushed in a direction, in which the circuit board 20 is disposed, when external force is applied and then return to its original state when the applying of the external force is released.

Although the contact part 300a in accordance with the first exemplary embodiment has the clip shape, the present disclosure is not limited thereto. For example, the contact part 300a may be a gasket.

That is, as described in the first modified example of the first exemplary embodiment of FIG. 2, the contact part 300b having a gasket shape may be disposed between the case 10 and the ESD protection part 400 to come into surface contact with the case 10. Here, the contact part 300b having the gasket shape may include an internal member 340 having elasticity and a conductive layer 350 disposed on a surface of the internal member.

Here, the internal member 340 may be formed by using a polymer synthetic resin such as polyurethane foam, polyvinyl chloride (PVC), silicone, ethylene vinylacetate copolymer, and polyethylene, rubber such as natural rubber (NR), styrene butadiene rubber (SBR), ethylene propylene diene monomer (EPDM) rubber, nitrile butadiene rubber (NBR), and neoprene, solid sheets, or a sponge sheet.

The conductive layer 350 may be disposed to surround an outer circumferential surface of the internal member. Also, the conductive layer may be made of various conductive materials such as carbon black, graphite, gold, silver, copper, nickel, and aluminum.

Also, as described in the second modified example of the first exemplary embodiment of FIG. 3, the internal member 340 may be an auxiliary member having a hole 360 to improve the elasticity of the gasket and an impact reducing effect. Here, the hole 360 may have various shapes such as a circular shape, an oval shape, and a polygonal shape.

As described above, the contact part 300a or 300b may come into contact with the case 10 of the electronic device, which is provided as the conductor. However, the contact part 300a or 300b may come into contact with any component of the electronic device, which is made of the conductive material. That is, the contact part 300a or 300b may be installed to come into contact with the conductor that serves as the antenna for transmitting an external communication signal.

Thereafter, in the description of the protection contactor in accordance with the exemplary embodiments, the contact part having the clip shape as illustrated in FIG. 1 will be described as an example. However, in all the exemplary embodiments, the contact part having the gasket shape as illustrated in FIGS. 2 and 3 may be applied.

The ESD protection part 400 blocks an electric shock voltage transmitted to the case (or the conductor) through the internal circuit of the circuit board 20 and bypasses an ESD voltage transmitted to the internal circuit through the case (or the conductor) from the outside.

The ESD protection part 400 in accordance with the first exemplary embodiment is provided as a protrusion 410. The protrusion 410 is disposed between the contact part 300a and the circuit board 20 and electrically connected to the contact part 300a. Also, as illustrated in FIG. 1, the protrusion 410 may extend from a position of the contact part 300a in the direction in which the circuit board 20 is disposed, and an end of the protrusion 410 toward the circuit board 20 may be spaced apart from the circuit board 20. The protrusion 410 is disposed to face a ground part of the circuit board 20.

The protrusion 410 in the exemplary embodiments is made of a material including the conductive material, for example, copper (Cu), but it not limited thereto. For example, the protrusion 410 may be made of at least one of Ag, Ag/Pd, Pd, Au, and Al.

The protrusion 410 may not be connected to the entire bottom surface of the coupling part 600a, but be partially or locally connected to the contact part 300a or the coupling part 600a. That is, the protrusion 410 has a length in a width direction thereof, that is less than that of each of the contact part 300a and the coupling part 600a and extends to the ground part of the circuit board 20. Thus, current due to an overvoltage or static electricity discharge(ESD) voltage that is above a discharge starting voltage introduced through the contact part 300a may concentratedly flow through the protrusion 410 that is the other conductor locally connected to the contact part 300a and disposed to face the ground part, and thereby to bypass the current. Also, since the protrusion 410 is spaced apart from the circuit board 20, the electric shock voltage transmitted to the case (or the conductor) through the internal circuit of the circuit board is blocked.

The protrusion 410 in accordance with the exemplary embodiments has a shape that gradually decreases in width from the position of the contact part 300a in the direction in which the circuit board 20 is disposed, for example, has a triangular shape in a cross-section. That is, the protrusion 410 may have a polygonal pyramid shape such as a triangular pyramid shape and a quadrangular pyramid shape, or a cone shape in the cross-section.

The shape of the protrusion 410 is not limited to the above-described triangular shape in the cross-section. For example, the protrusion 410 may have any shape as long as the protrusion 410 is locally connected to the contact part 300a or the coupling part 600a to protrude to the circuit board. That is, the protrusion 410 may have a triangular bar shape or a polygonal bar shape in the cross-section.

As described above, since the protrusion 410 is disposed to be connected to a portion of the contact part 300a, the current due to the overvoltage or ESD voltage that is above the discharge starting voltage introduced into the contact part 300a may be concentrated into the protrusion 410 and then be more easily bypassed to the ground part to more improve the static electricity prevention effect.

Although only one ESD protection part 400 having the protrusion 410 is provided, the present disclosure is not limited thereto. For example, a plurality of ESD protection parts may be provided.

The capacitor part 500 may be disposed between the contact part 300a and the circuit board 20 to transmit a communication signal, which is introduced from the case 10 that serves as the antenna, therethrough.

In the electric shock protection contactor in accordance with the first exemplary embodiment, the capacitor part 500 may be disposed in each of both directions of the ESD protection part 400, and the pair of capacitor parts 500 may be installed to be spaced apart from each other in both the directions with respect to the protrusion 410.

The capacitor part 500 includes a laminate 510 in which at least one sheet is laminated, first and second external electrodes 521 and 522 respectively disposed on an outer surface of the laminate 510, which faces the case 10, and an outer surface of the laminate 510, which faces the circuit board 20, and a plurality of internal electrodes 523 and 524 extending to cross the first and second external electrodes 521 and 522 in the laminate 510 and arranged to be alternately connected to the first and second external electrodes 521 and 522.

The laminate 510 may be formed by laminating a plurality of sheets, each of which is made of at least one of a dielectric, ceramic, and varistor.

The external electrodes 521 and 522 are disposed on the outer surface of the laminate 510. In detail, the external electrodes 521 and 522 are disposed on the outer surface of the laminate 510, which faces the case 10, and the outer surface of the laminate 510, which faces the circuit board 20, respectively. That is, the first external electrode 521 is disposed on a top surface of the laminate 510, and the second external electrode 522 is disposed on a bottom surface of the laminate 510. Here, the first external electrode 521 is electrically connected to the case 10 through the coupling part 600a and the contact part 300a, and the second external electrode 522 is electrically connected to the circuit board 20. The first and second external electrodes 521 and 522 in accordance with the exemplary embodiments may be made of a metal material, for example, at least one of Ag, Ag/Pd, Cu, Pd, Au, and Al.

Each of the plurality of internal electrodes 523 and 524 may extend in a direction crossing the external electrodes 521 and 522 in the laminate 510 and be connected to each of the external electrodes 521 and 522. That is, the plurality of internal electrodes 523 vertically extend in the laminate 510. Here, one portion of the plurality of internal electrodes 523 and 524 is connected to the first external electrode 521, the other portion is connected to the second external electrode 522. Hereinafter, the internal electrode connected to the first external electrode 521 is called the first internal electrode 523, and the internal electrode connected to the external electrode 522 is called the second internal electrode 524.

One end of the first internal electrode 523 is connected to the first external electrode 521 to extend in a direction in which the second external electrode 522 is disposed, and the other end is spaced apart from the second external electrode 522. On the other hand, one end of the second internal electrode 524 is connected to the second external electrode 522 to extend in a direction in which the first external electrode 521 is disposed, and the other end is spaced apart from the first external electrode 521.

A capacitor C is provided in the laminate 510 by the capacitor part 500. That is, the capacitor part 500 includes the capacitor C constituted by the first and second internal electrodes 523 and 524 and the laminate 510 between the first and second internal electrodes 523 and 524.

In other words, in the electric shock protection contactor 1000 in accordance with the exemplary embodiments, the capacitor part 500 is disposed in a lateral direction of the ESD protection part 400 at the same height or on the same plane as the ESD protection part 400. Also, each of the capacitor part 500 and the ESD protection part 400 are connected to the contact part 300a and the circuit board 20, respectively.

A configuration including the above-described capacitor part 500 and the ESD protection part 400 may be called an “electric shock protection part”. That is, the electric shock protection contactor 1000 includes the electric shock protection part disposed between the contact part 300a and the circuit board 20. The electric shock protection part includes the capacitor part 500 and the ESD protection part 400.

Although two capacitor parts 500 are provided, the present disclosure is not limited thereto. For example, one capacitor part or two or more capacitor parts may be provided. Also, the two capacitor parts 500 may be provided. Here, one capacitor part may be disposed on one side of the ESD protection part 400, and the other capacitor part may be disposed on the other side of the ESD protection part 400. However, the present disclosure is not limited thereto. For example, the plurality of capacitor parts 500 may be disposed on at least one of the one side and the other side of the ESD protection part 400.

Also, although one ESD protection part is provided between two capacitor parts 500, the present disclosure is not limited thereto. For example, a plurality of ESD protection parts may be disposed between the two capacitor parts.

The coupling part 600a is disposed between the contact part 300a, the ESD protection part 400, and the capacitor part 500 to couple the contact part 300a, the ESD protection part 400, and the capacitor part 500 to each other. The coupling part 600a in accordance with the exemplary embodiments may be a conductive adhesion layer having conductivity and adhesion functions. The conductive adhesion layer is applied to a bottom surface of the contact part 300a. Here, when a top surface of the capacitor part 500 and a top surface of the ESD protection part 400 come into contact with each other, the contact part 300a, the capacitor part 500, and the ESD protection part 400 may be bonded to each other by the conductive adhesion layer. Here, the current due to the overvoltage or ESD voltage that is above the discharge starting voltage introduced into the contact part 300a and the communication signal may be transmitted to the capacitor part 500 or the ESD protection part 400 through the conductive adhesion layer.

In this embodiment, although the capacitor part and the ESD protection part are coupled to the contact part by the coupling part 600a, the present disclosure is not limited thereto. For example, the coupling part 600a may be omitted.

Hereinafter, the electric shock protection contactor 1000 in accordance with the first exemplary embodiment will be described again in view of a position relationship between the capacitor part 500 and the ESD protection part 400.

Referring to FIG. 1, the electric shock protection contactor 1000 includes the contact part 300a coming into contact with the case 10 and having the elasticity, the capacitor part 500 disposed between the contact part 300a and the circuit board 20 and having one side connected to the contact part 300a and the other side connected to the circuit board 20, and the ESD protection part 400 disposed between the contact part 300a and the circuit board 20 and having at least one side connected to the contact part 300a. Also, the electric shock protection contactor 1000 may include the coupling part 600a coupling the capacitor part 500 and the ESD protection part 400 to the contact part 300a.

In the first exemplary embodiment, the capacitor part 500 is disposed on each of both sides of the ESD protection part 400, and the ESD protection part 400 and the first and second capacitor parts 500 are disposed at the same height or on the same plane as each other. Thus, each of the ESD protection part 400 and the capacitor part 500 has an upper portion connected to the contact part 300a and a lower portion connected to the circuit board 20. In the electric shock protection contactor 1000, the ESD protection part 400 and the capacitor C may not overlap each other. That is, in other words, the ESD protection part and the capacitor C are different in positions in a width direction.

In the exemplary embodiments, the ESD protection part 400 includes the protrusion 410. However, the present disclosure is not limited thereto. For example, the ESD protection part 400 may include various electric shock protection devices having the ESD protection function, for example, a varistor type electric shock protection device and a suppressor type electric shock protection device.

In the electric shock protection contactor 1000 in accordance with the modified examples of the first exemplary embodiment and the second to fourth exemplary embodiments, which will be described below, as described above, the ESD protection part 400 and the capacitor part 500 are disposed between the contact part 300a and the circuit board 20 so that one side of each of the ESD protection part 400 and the capacitor part 500 is connected to the contact part 300a, and the other side is connected to the circuit board 20. Also, the ESD protection part 400 and the capacitor C do not overlap each other. Similarly, the present disclosure is not limited to the ESD protection part 400 including the protrusion 410. For example, various electric shock protection devices having the ESD protection function, for example, a varistor type electric shock protection device and a suppressor type electric shock protection device may be applied to the ESD protection part 400.

Also, the first to seventh exemplary embodiments may be variously combined with each other.

In accordance with the first exemplary embodiment, the capacitor part 500 and the ESD protection part 400 are spaced apart from each other. However, the present disclosure is not limited thereto. For example, the capacitor part 500 and the ESD protection part 400 may be connected to each other.

That is, as described in the second exemplary embodiment of FIG. 4, a plurality of capacitor parts 500, for example, the first and second capacitor parts 500 may be disposed with the ESD protection part 400 therebetween. Here, each of the first and second capacitor parts 500 may be bonded or connected to the ESD protection part 400. Here, the first and second capacitor parts 500 may be disposed at the same height or on the same plane as the ESD protection part 400, and the capacitor C of each of the first and second capacitor parts 500 may not overlap the ESD protection part 400 in the formation position thereof.

To bond or connect the capacitor part 500 to the ESD protection part 400, the ESD protection part 400 in accordance with the first modified example of the first exemplary embodiment further include a block 420 accommodating the protrusion 410. That is, the ESD protection part 400 (see (a) of FIG. 5) in accordance with the first exemplary embodiment includes only the protrusion 410, but the ESD protection part 400 in accordance with the first modified example of the first exemplary embodiment includes the block 420 and the protrusion 410 inserted into the block 420. Here, the outside of the protrusion 410 in the block 420 may be provided as an empty space. The block 420 may be made of the same material as the laminate 510 of the capacitor part 500, for example, a dielectric or ceramic.

To manufacture the electric shock protection contactor in accordance with the second exemplary embodiment, the ESD protection part 400, into which the protrusion 410 and an auxiliary member 430 are inserted, and the capacitor part 500 are provided in the block 420. Here, the ESD protection part 400 and the capacitor part 500 are bonded to each other. Here, the capacitor part 500 may be disposed in a lateral direction of the ESD protection part 400. For this, the capacitor part 500 may be connected to each of one side and the other side of the ESD protection part 400.

The ESD protection part 400 is not limited to the shape in accordance with the first exemplary embodiment and the first modified example. For example, the ESD protection part 400 may further include the other component in addition to the protrusion in the block 420. That is, as illustrated in (c) and (d) of FIG. 5, the auxiliary member 430 facing the protrusion 410 may be further provided under the protrusion 410 in the block 420. The auxiliary member 430 may have a shape in which a width thereof gradually decreases in a direction in which the protrusion 410 is disposed (the ESD protection part in accordance with the second modified example of the first exemplary embodiment in (c) of FIG. 5) or a shape in which the top and bottom surfaces thereof have the same width, i.e., a rectangular shape in cross-section (the ESD protection part in accordance with the third modified example of the first exemplary embodiment in (d) of FIG. 5).

As illustrated in FIGS. 6 and 7, the ESD protection part in accordance with the second and third modified examples of the first exemplary embodiment may also be connected to the capacitor part 500 between the contact part 300a and the circuit board 20.

Hereinabove, the ESD protection part 400 in which the protrusion 410 and the auxiliary member 430 are inserted into the block 420 has been described. However, the present disclosure is not limited thereto. For example, the protrusion 410 and the auxiliary member 430 may face each other without providing the block 420.

In the ESD protection part 400 in accordance with the first exemplary embodiment, the outside of the protrusion in the block 420 is provided as the empty space (see FIGS. 1 to 4 and (a) and (c) of FIG. 5). However, the present disclosure is not limited thereto. For example, the block 420 may be made of an ESD protection material including at least one of the varistor and the ESD discharge material. Thus, like the ESD protection part 400 in accordance with the second exemplary embodiment of (e) of FIG. 5, the protrusion 410 may be inserted into the block 420 made of the ESD protection material. Alternatively, like the modified example of the second exemplary embodiment of (f) of FIG. 5, a coating film 421 to which the ESD protection material including at least one of the varistor and the ESD discharge material is applied may be provided on an outer surface of the block 420 that is the empty space.

Here, the varistor material forming the block 420 may be a material including at least one of ZnO, Bi₂O₃, Pr₆O₁₁, Co₃O₄, Mn₂O₃, CaCO₃, SrTiO₃, and BaTiO₃.

Also, the ESD discharge material forming the block 420 may be a porous insulation material or a conductive material. That is, the block 420 may be made of a mixture in which the porous insulation material and the conductive material are mixed with each other. Alternatively, an insulation layer made of the porous insulation material and a conductive layer made of the conductive material may be laminated at least one time to form the block. Here, the conductive material may be conductive ceramic. The conductive ceramic may be a mixture including at least one of La, Ni, Co, Cu, Zn, Ru, Ag, Pd, Pt, W, Fe, and Bi. The insulation material mixed with the conductive material may be used as the discharge inducing material and serve as an electrical barrier having a porous structure. The insulation material may be insulation ceramic. The insulation ceramic may include a ferroelectric material having a dielectric constant of approximately 50 to approximately 50,000. For example, the insulation ceramic may be a mixture including at least one of dielectric material powder such as MLCC, BaTiO₃, BaCO₃, TiO₂, Nd, Bi, Zn, and Al₂O₃.

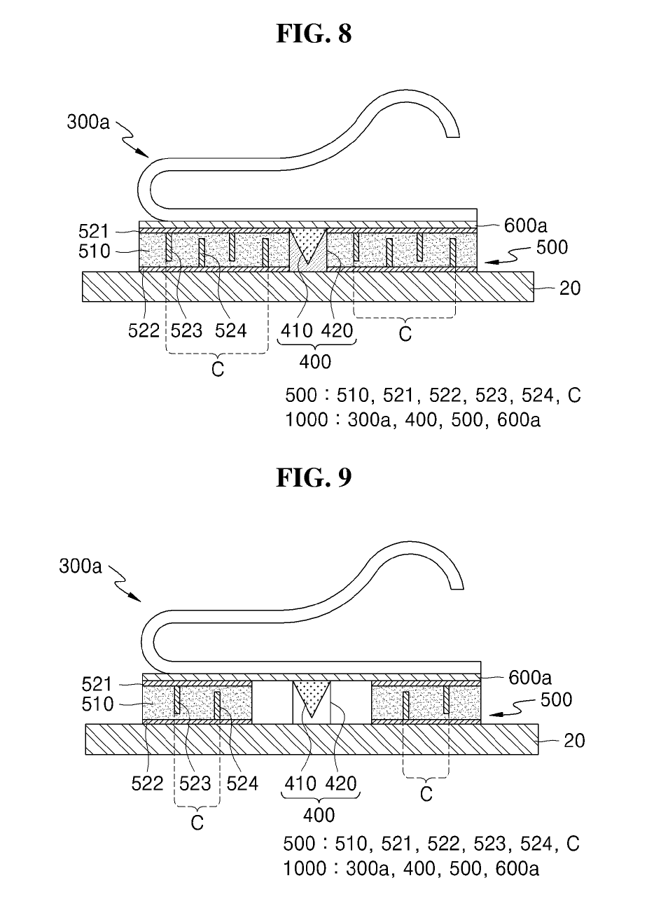

When the ESD protection part in accordance with the second exemplary embodiment is applied to the electric shock protection contactor in accordance with the second exemplary embodiment, for example, the configuration illustrated in FIG. 8 may be realized. That is, in the electric shock protection contactor 1000 in accordance with the third modified example of the second exemplary embodiment of FIG. 8, the capacitor part 500 is disposed to be connected to the ESD protection part 400. Here, the outer surface of the laminate 510 of the capacitor part 500 and the outer surface of the block made of the ESD protection material may be connected to each other.

Although not shown, the ESD protection part 400 in accordance with the modified example of the second exemplary embodiment may be applied to the electric shock protection contactor in accordance with the second exemplary embodiment.

Hereinabove, the ESD protection part 400 in accordance with the first to third modified examples of the first exemplary embodiment and the ESD protection part 400 in accordance with the second exemplary embodiment are applied to the electric shock protection contactor in accordance with the second exemplary embodiment. However, the present disclosure is not limited thereto. For example, the first exemplary embodiment in which the capacitor part 500 and the ESD protection part 400 are spaced part from each other may be applied.

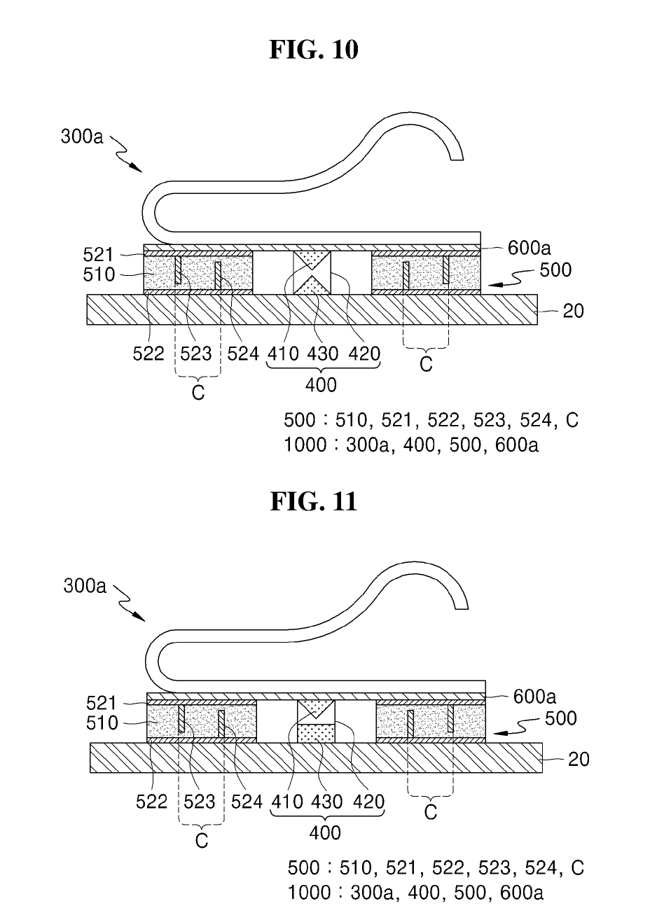

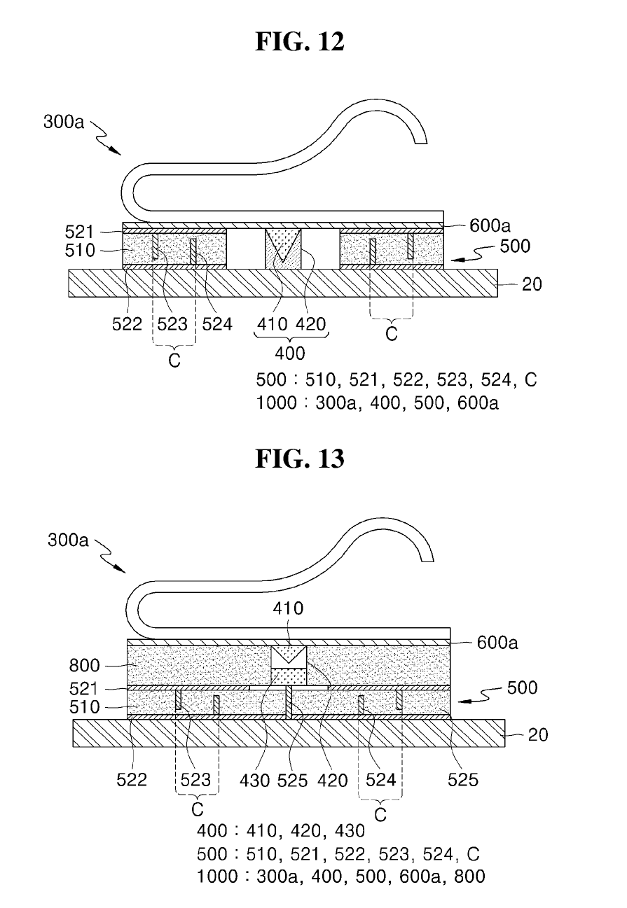

That is, when the ESD protection part 400 in accordance with the first to third modified examples of the first exemplary embodiment and the ESD protection part 400 in accordance with the second exemplary embodiment are applied to the electric shock protection contactor in accordance with the second exemplary embodiment, the configurations illustrated in FIGS. 9 to 12 may be realized. That is, the ESD protection part 400 may be disposed between the plurality of capacitor parts 500, and also, the ESD protection part 400 may include the block 420 and the protrusion 410 inserted into the block 420. Also, the ESD protection part 400 may further include the auxiliary member 430 disposed to face the protrusion 410 in the block 420 (see FIGS. 10, 11, and 12). Alternatively, the block 420 may be provided as the empty space (see FIGS. 9, 10, and 11), be made of the ESD protection material (see FIG. 12), or may further include the coating film 421, to which the ESD protection material is applied, on the outer surface thereof.

Here, in the ESD protection part 400, the outer surface of the block 420 facing the capacitor part 500 may be spaced apart from the capacitor part 500.

In the electric shock protection contactor in accordance with the second and third exemplary embodiments, the capacitor part 500 is disposed in the lateral direction of the ESD protection part 400.

However, the present disclosure is not limited thereto. For example, like the third exemplary embodiment of FIG. 13, the capacitor part 500 may be disposed under the ESD protection part 400. That is to say, the capacitor part 500 and the ESD protection part 400 may be disposed at the same height in the first and second exemplary embodiments, but be disposed at heights different from each other in the third exemplary embodiment. That is, the capacitor part 500 may be disposed between the ESD protection part 400 and the circuit board 20.

Here, to stably couple the ESD protection part 400 to the capacitor part 500, a support part 800 may be further provided in a lateral direction of the ESD protection part 400. The capacitor part 500 is connected to lower portions of the support part 800 and the ESD protection part 400.

That is, a plurality of support parts 800 are provided, and the ESD protection part 400 is disposed between the plurality of support parts 800. The plurality of support parts 800 and the ESD protection part 400 are arranged to extend in the width direction of the contact part 300a. The support part 800 may be formed by laminating a plurality of sheets, each of which is made of at least one of a dielectric, ceramic, and varistor.

Since the capacitor part 500 in accordance with the third exemplary embodiment is disposed below the ESD protection part 400, the capacitor part 500 further include a connection electrode 525 electrically connecting the ESD protection part 400 to the circuit board 20. That is, the capacitor part 500 in accordance with the third exemplary embodiment includes the laminate 510, the pair of first external electrodes 521 spaced apart from each other with respect to the ESD protection part 400 on the top surface of the laminate 510, the second external electrode 522 disposed on the bottom surface of the laminate 510, the first and second internal electrodes 523 and 524 respectively extending to cross the external electrodes 521 and 522 in the laminate 510 and arranged to correspond to the extension direction of the first and second external electrodes 521 and 522, and the connection electrode 525 extending in a direction corresponding to the internal electrodes 523 and 524 in the laminate 510 and having one end connected to the ESD protection part 400 and the other end connected to the second external electrode 522.

The connection electrode 525 may be made of at least one of Ag, Ag/Pd, Cu, Pd, Au, and Al.

In the capacitor part 500, the first and second internal electrodes 523 and 524 are disposed on both sides with the connection electrode 525 therebetween in the laminate 510. That is, the first internal electrode 523 is disposed on one side of the connection electrode 525 in the laminate 510, and the second internal electrode 524 is disposed on the other side of the connection electrode 525. Also, the first internal electrode 523 is connected to the first external electrode 521, and the second internal electrode 524 is connected to the second external electrode 522. Also, the capacitors C are disposed on both sides of the connection electrode 525.

Also, the second and third modified examples of the first exemplary embodiment in which the ESD protection part 400 includes the auxiliary member 430 to be connected to the connection electrode 525 may be applied. The connection electrode 525 has one end connected to the auxiliary member 430 of the ESD protection part 400. Although the ESD protection part (see (c) of FIG. 5) in accordance with the third modified example of the first exemplary embodiment is applied in FIG. 13, the ESD protection part (see (d) of FIG. 5) in accordance with the third modified example of the first exemplary embodiment may be applied.

Hereinafter, the electric shock protection contactor 1000 in accordance with the third exemplary embodiment will be described again in view of a position relationship between the capacitor part 500 and the ESD protection part 400.

Referring to FIG. 13, the electric shock protection contactor 1000 includes the contact part 300a coming into contact with the case 10 and having the elasticity, the ESD protection part 400 having one side connected to the contact part 300a, and the capacitor part 500 disposed between the ESD protection part 400 and the circuit board 20 and having one side connected to the ESD protection part 400 and the other side connected to the circuit board 20. Also, the electric shock protection contactor 1000 may include the support parts 800 disposed on both sides of the ESD protection part 400 and the coupling part 600a coupling the capacitor part 500 and the ESD protection part 400 to the contact part 300a.

In the third exemplary embodiment, the capacitor part 500 may be disposed at a height different from that of the ESD protection part 400, i.e., disposed below the ESD protection part 400. Also, the internal electrodes 523 and 524 of the capacitor part 500 are disposed on both sides with the ESD protection part 400 therebetween in the laminate 510. That is to say, the internal electrodes 523 and 524 may be disposed at positions different from that of the ESD protection part in the width direction thereof. Thus, the capacitor C including the internal electrodes 523 and 524 and the ESD protection part 400 do not overlap each other.

In the third exemplary embodiments, the ESD protection part 400 includes the protrusion 410. However, the present disclosure is not limited thereto. For example, the ESD protection part 400 may include various electric shock protection devices having the ESD protection function, for example, a varistor type electric shock protection device and a suppressor type electric shock protection device.

In the electric shock protection contactor 1000 in accordance with the fifth exemplary embodiment, which will be described below, as described above, the ESD protection part 400 and the capacitor part 500 are disposed between the contact part 300a and the circuit board 20, the contact part 300a is connected to one side of the ESD protection part 400, and the capacitor part 500 is connected to the ESD protection part 400 and the circuit board 20. Also, the ESD protection part 400 and the capacitor C do not overlap each other.

Similarly, the present disclosure is not limited to the ESD protection part 400 including the protrusion 410. For example, various electric shock protection devices having the ESD protection function, for example, a varistor type electric shock protection device and a suppressor type electric shock protection device may be applied to the ESD protection part 400.

In the electric shock protection contactor 1000 in accordance with the first to third exemplary embodiments, the ESD protection part 400 is connected to a bottom surface of the contact part 300a or the coupling part (the adhesion layer).

However, the present disclosure is not limited thereto. For example, the ESD protection part 400 may be coupled to a side surface of the contact part 300a or the coupling part (the adhesion layer). That is, like the fourth exemplary embodiment of FIG. 14, the ESD protection part 400 including the protrusion 410 may be connected to side surfaces of the contact part 300a, the coupling part 600a, and the capacitor part 500. Also, an end of one side surface of the protrusion 410, which is directed to the circuit board 20, is spaced apart from the circuit board 20 and disposed to face the ground part of the circuit board 20 so that the protrusion 410 faces the circuit board 20.

As illustrated in FIG. 14, a length of the capacitor part 500 in the width direction thereof may extend by a length corresponding to each of the contact part 300a and the coupling part.

In the electric shock protection contactor in accordance with the fourth exemplary embodiment, the capacitor part 500 and the ESD protection part 400 are disposed between the case 10 and the circuit board 20, one side surface and the other side surface of the capacitor part 500 are respectively connected to the contact part 300a and the circuit board 20, the ESD protection part 400 is connected to the contact part 300a, and the capacitor C and the ESD protection part 400 do not overlap each other.

Although the protrusion 410 comes into contact with the contact part 300a, the coupling part 600a, and the capacitor part 500 in the third exemplary embodiment, the protrusion 410 may not come into direct contact with the contact part 300a, but come into contact with the coupling part 600a and the capacitor part 500.

Also, although the ESD protection part is provided as only the protrusion 410 in FIG. 14, the present disclosure is not limited thereto. For example, the ESD protection part in accordance with the first to third modified examples of the first exemplary embodiment and the second exemplary embodiment of FIG. 5 may be applied.

For another example, a discharge member 700 for bypassing the current due to the overvoltage or the ESD voltage that is above the discharge starting voltage may be additionally provided in the lateral direction of the contact part 300a in addition to the ESD protection part including the protrusion 410. That is, like the first modified example of the fourth exemplary embodiment of FIG. 15, the discharge member 700 is disposed to come into contact with the side surface of the capacitor part 500, and the protrusion 410 is disposed to be connected to the side surface of the discharge member 700. That is to say, one side surface of the discharge member 700 is connected to the side surface of the capacitor part 500, and the other side surface of the discharge member 700 is connected to the protrusion 410.

The discharge member 700 may be formed by applying the ESD protection material including at least one of the varistor and the ESD discharge material to the side surface of the capacitor part 500. The varistor material may be a material including at least one of ZnO, Bi₂O₃, Pr₆O₁₁, Co₃O₄, Mn₂O₃, CaCO₃, SrTiO₃, and BaTiO₃. Also, the ESD discharge material may be a porous insulation material or a conductive material.

Also, the ESD protection part 400 may be provided as only the protrusion, like the first modified example of FIG. 15, or the ESD protection part 400 further including the auxiliary member below the protrusion 410 may be applied, like the second modified example of FIG. 16. That is, the discharge member 700 is disposed on the side surface of the capacitor part 500, and the protrusion 410 and the auxiliary member 430 are disposed to be spaced apart from each other on the other side surface of the discharge member 700.

In the abovementioned first to fourth exemplary embodiment, the contact part 300a and the ESD protection part 400 are bonded or coupled to each other by using the coupling part 600a provided as the conductive adhesion layer.

However, the present disclosure is not limited thereto. For example, the contact part 300a and the ESD protection part 400 may be mechanically coupled to each other. Here, the coupling part may be, for example, a joint.

Referring to FIGS. 17 to 19, the electric shock protection contactor in accordance with the fifth exemplary embodiment includes the contact part 300a having elasticity, the capacitor part 500 disposed between the contact part 300a and the circuit board 20, the coupling part 600b physically or mechanically coupling the capacitor part 500 to the contact part 300a, and the ESD protection part 400 disposed to be connected to the coupling part 600b and the capacitor part 500 and including the protrusion 410 extending in the direction in which the circuit board 20 is disposed.

That is, the electric shock protection contactor in accordance with the fifth exemplary embodiment includes the capacitor part 500 and the ESD protection part 400, which are similar to those of the fourth exemplary embodiment of FIG. 14. Here, the coupling part 600b may not be provided as the conductive laminate, but have a coupling function.

Explaining again the arrangement structure of the capacitor part 500 and the ESD protection part 400 in the electric shock protection contactor in accordance with this embodiment, the ESD protection part 400 is disposed in the lateral direction of the capacitor part 500.

Hereinafter, for explaining the coupling part 600b including the coupling member, a constitute disposed between the contact part 300a and the circuit board 20 and including the ESD protection part 400 and the capacitor part 500 is called an “electric shock protection part 50”. That is, the electric shock protection part 50 is disposed between the contact part 300a and the circuit board 20, and also, the electric shock protection part 50 includes the ESD protection part 400 and the capacitor part 500.

The electric shock protection part 50 in accordance with the exemplary embodiments has an alphabet “T” shape with a protrusion area. This is done because of being easily coupled to the coupling part.

Explaining again the electric shock protection part 50 in views of the entire shape or configuration of the electric shock protection part 50, the electric shock protection part 50 includes a first area A1 extending in an X axis direction (a first direction) and a second area A2 disposed below the first area A1 and extending in the X axis direction (the first direction) and a Y axis direction (a second direction) so that the second area A2 has a surface area less than that of the first area A1.

Here, the Y axis (the second direction) crossing the X axis (the first direction) of the first area A1 has a length greater than that of the Y axis (the second direction) of the second area A2, and thus, an end of the Y axis (the second direction) of the first area A1 further protrudes from the second area A2. That is, the first area A1 has a protrusion area P that further protrudes from the second area A2 in the Y axis direction. Here, the second area A2 may be disposed at a center below the first area A1. Thus, the first area A1 may have the protrusion area P toward both sides in the Y axis direction with respect to the second area A2. Also, the length of the X axis (the first direction) of the first area A1 may be the same as that of the X axis (the first direction) of the second area A2.

The entire configuration of the electric shock protection part 50 includes the first area A1 and the second area A2 and has the alphabet “T” shape.

Each of the above-described first and second areas A1 and A2 may represent an “area”, “space”, or “position” in which the capacitor part 500 and the ESD protection part 400 are provided.

Thus, explaining the electric shock protection part 50 again, the electric shock protection part 50 includes the first area A1 and the second area A2 to form the alphabet “T” shape.

The coupling part 600b is coupled to grip the protrusion area P of at least the first area A1. That is, the coupling part 600b is coupled to grip at least one of the capacitor part 500 and the ESD protection part 400, which are disposed on the protrusion area P of the first area A1, of the capacitor part 500 and the ESD protection part. That is to say, the coupling part 600b is coupled to grip a potion of at least one of the capacitor part 500 and the ESD protection part 400, which are disposed to correspond to the protrusion area P of the first area A1.

Each of the first area A1 and the second area A2 of the electric shock protection contactor 1000 in accordance with the fifth exemplary embodiment includes the capacitor part 500, and the ESD protection part 400 is connected to one end of the capacitor part 500. That is to say, the capacitor part 500 is disposed on each of the first area A1 and the second area A2. This does not mean that the first area A1 and the second area A2 are separately provided. That is, this means that the capacitor part 500 is disposed over the first area A1 and the second area A2.

Also, the ESD protection part 400 is disposed on the side surface of the capacitor part 500, i.e., in a lateral direction of the first and second areas A1 and A2.

Hereinafter, the electric shock protection contactor in accordance with the fifth exemplary embodiment will be described in more detail.

The capacitor part 500 includes the laminate 510 in which at least one sheet is laminated, the first and second external electrodes 521 and 522 respectively disposed on an outer surface of the laminate 510, which faces the case 10 or the coupling part 600b, and an outer surface of the laminate 510, which faces the circuit board 20, and the plurality of internal electrodes 523 and 524 extending to cross the first and second external electrodes 521 and 522 in the laminate 510 and arranged to be alternately connected to the first and second external electrodes 521 and 522.

Referring to FIGS. 17 to 19, the laminate 510 has a shape with a long side and a short side, for example, an alphabet “T” shape when viewed in the short side direction. Hereinafter, a long side direction of the capacitor part 500 is defined as the X axis direction (or the first direction), and the short side direction is defined as the Y axis direction (or the second direction).

Here, in other wards, the X axis direction may be a direction in which the plurality of internal electrodes are arranged, and the Y axis direction may be a direction that crosses or is perpendicular to the X axis direction.

As described above, the laminate 510 has the alphabet “T” shape in entire shape or cross-section when viewed in the short side direction. In detail, the laminate 510 includes an upper laminate 510a and a lower laminate 510b, which are vertically laminated. The upper and lower laminates 510a and 510b have lengths corresponding or similar to each other in the X direction or have the same length in the X direction. Also, the upper laminate 510a has a length greater than that of the lower laminate 510b in the Y direction. Thus, a structure in which the upper and lower laminates 510a and 510b are vertically coupled to each other has an approximately alphabet “T” shape. That is, as illustrated in FIG. 18, the upper laminate 510a further protrudes to both sides in the Y axis direction with respect to the lower laminate 520, and the protruding portion of the upper laminate 510a may be a portion to be coupled to the coupling part 600b.

Although the upper and lower laminates 510a and 510b are separately provided, the laminate 510 may be provided as one body.

Here, each of the upper and lower laminates 510a and 510b may be formed by laminating a plurality of sheets, each of which is made of at least one of a dielectric, ceramic, and varistor.

The first external electrode 521 is disposed on each of top and side surfaces of the upper laminate 510a and connected to the first internal electrode 523, and the second external electrode 522 is disposed on a bottom surface of the lower laminate 510b and connected to the second internal electrode 524. The first and second external electrodes 521 and 522 may be formed by applying a conductive material, for example, at least one of Ag, Ag/Pd, Cu, Pd, Au, and A1 to an outer surface of the laminate through a printing method.

As illustrated in FIG. 20, plating layers 526a and 526b may be further disposed on at least one outer surface of the first and second external electrodes 521 and 522. For example, a Ni-plated layer and Sn or Sn/Ag-plated layer may be laminated.

After the first and second plating layers 526a and 526b are respectively disposed on the outer surfaces of the first and second external electrodes 521 and 522, an upper portion of the capacitor part 500 comes into contact with the coupling part 600b and is coupled to the coupling part 600b, and then, a lower portion of the capacitor part 500 comes into contact with the circuit board 20. Also, when each of the first and second plating layers 526a and 526b is heated, the first and second plating layers 526a and 526b may be melted and thus bonded or coupled to the coupling part 600b and the circuit board 20.

As described above, the electric shock protection contactor in accordance with the fifth exemplary embodiment includes the coupling part 600b having the coupling function. That is, the coupling part 600b may be configured to grip the top surface of the upper laminate 510a and the protrusion area P of the upper laminate 510a, which further protrudes from the lower laminate 510b in the Y axis direction.

In more detail, the coupling part 600b includes an upper coupling member 610 disposed to correspond to the top surface of the upper laminate 510a when coupled to the coupling part 600b and extending in a direction corresponding to the extension directions of the X axis and the Y axis of the upper laminate 510a, a side coupling member 620 extending downward from each of both ends of the upper coupling member 610 in the Y axis direction, and a lower coupling member 630 extending from the side coupling member 620 in the Y axis direction to correspond to the bottom surface of the upper laminate 510a that protrudes from the lower laminate 510b in the Y axis direction.

As described above, the coupling part 600b is coupled to grip the protrusion area P of the electric shock protection part 50. Here, an edge of the upper coupling member 610 is coupled to a top surface of the protrusion area P, the side coupling member 620 is coupled to a side surface of the protrusion area P, and the lower coupling member 630 is coupled to a bottom surface of the protrusion area P.

Here, an empty space is defined between the upper, side, and lower coupling members 610, 620, and 630 of the coupling part 600b. At least the upper laminate 510a of the capacitor part 500 is accommodated into the empty space. The coupling part 600b may be made of a conductive material, for example, copper (Cu).

The contact part 300a may be integrated with the coupling part 600b. For example, the contact part 300a includes the first extension 310 and the third extension 330. The third extension 330 may be integrally connected to the upper coupling member 610 of the coupling part 600b. Here, the second extension 320 of the contact part 300a may be substituted with the coupling part 600b or the upper coupling member 610 of the coupling part 600b.

The ESD protection part in accordance with the fifth exemplary embodiment, i.e., the protrusion 410 may be connected to a side of the coupling part 600b. That is, the protrusion 410 is connected to the coupling part 600b or one side surface of the upper coupling member 610 in the X axis direction and extends in a direction in which the lower laminate 510b is disposed. Also, an end of the protrusion 410 is spaced apart from the circuit board 20. Also, the protrusion 410 has one surface coming into contact with the upper and lower laminates 510a and 510b of the capacitor part 500.

The protrusion 410 may be integrated with the coupling part 600b or be separately provided and then connected to the coupling part 600b.

As described above, an upper end of the protrusion 410 is connected to the coupling part 600b, and one side surface of the protrusion 410 comes into contact with the side surface of the capacitor part 500. Thus, the shape defined by the ESD protection part including the protrusion 410 and the capacitor part 500 or the entire shape defined by the electric shock protection part 50 may be the alphabet “T” shape.

As described above, when the coupling part 600b is coupled to each other the capacitor part 500, the upper laminate 510a may be coupled in a manner in which the upper laminate 510a is inserted into the space between the upper, side, and lower coupling members 610, 620, and 630. That is, the contact part 300a and the capacitor part 500 are mechanically coupled to the capacitor part 500 by the coupling part 600b.

As described above, when the contact part 300a and the capacitor part 500 or the ESD protection part 400 are mechanically coupled to each other by using the coupling part 600b including the coupling member or the joint, but does not including the conductive adhesion layer, resistance may be lowered when compared to that in accordance with the first to fourth exemplary embodiments using the conductive adhesive.

Although not shown, the discharge member 700 may be further provided to come into contact with the side surface of the capacitor part 500 (see FIG. 15). Also, the ESD protection part 400 may further include the auxiliary member to face the protrusion (see FIG. 16).

In the abovementioned fifth exemplary embodiment, the coupling part having the coupling function in the structure in which the ESD protection part 400 is disposed on the side surface of the coupling part 600b and the capacitor part 500 is applied.

However, the present disclosure is not limited thereto. For example, the plurality of capacitor parts 500 may be provided, and the coupling part 600b having the coupling function may be applied to the electric shock protection contactor in which the ESD protection part 400 is disposed between the plurality of capacitor parts 500.

For example, like the sixth exemplary embodiment of FIGS. 21 to 23, the capacitor part 500 may be disposed on each of both sides of the ESD protection part 400, and the pair of capacitor parts 500 may be spaced apart from each other in both directions with respect to the ESD protection part 400, i.e., the protrusion 410.

The electric shock protection part 50 in accordance with the sixth exemplary embodiment has an alphabet “T” shape with the protrusion area P in the entire shape thereof.

In detail, the first area A1 and the second area A2 include the capacitor part 500. That is, the capacitor part 500 is disposed on each of the first area A1 and the second area A2. Here, the capacitor part 500 may be provided in plurality, for example, in a pair, and the pair of capacitor parts 500 are spaced apart from each other in the first direction. Also, the protrusion 410 is disposed between the pair of capacitor parts 500. The protrusion 410 extends from an area A1 to an area A2.

Due to the above-described arrangement of the capacitor parts 500 and the protrusion 410, the entire shape of the electric shock protection part 50 when viewed from the outside may have a shape with the protrusion area P, for example, have the “T” shape.

Each of the pair of capacitor parts 500 has the alphabet “T” shape in entire outer appearance as illustrated in FIGS. 21 and 22. That is, the laminate 510 of each of the pair of capacitor parts 500 has a structure in which the upper and lower laminates 510a and 510b are laminated. Here, the upper laminate 510a extends to further protrude from the lower laminate 510b in the Y axis direction. Also, the first and second external electrodes 521 and 522 are disposed on the outer surface of the laminate 510, and the internal electrodes 523 and 524 are disposed in the laminate 510 to form the capacitor part 500.

The pair of capacitor parts 500 having the above-described structure may be separately manufactured and then disposed to be spaced apart from each other in the X axis direction. Here, the protrusion 410 is disposed between the pair of capacitor parts 500.

The protrusion 410 is connected to or integrated with the coupling part to correspond between the pair of capacitor parts 500. That is, the protrusion 410 is disposed on the bottom surface of the upper coupling member 610 of the coupling part 600b. Here, the protrusion 410 is disposed on the upper coupling member 610 to correspond between the pair of capacitor parts 500.

Also, since the protrusion 410 is coupled to the bottom surface of the upper coupling member 610, and the capacitor part is disposed on each of both sides of the protrusion 410, the shape defined by the ESD protection part 400 and the capacitor part 500 or the entire shape of the electric shock protection part 50 may have the alphabet “T” shape.

The coupling part 600b is coupled to grip the upper and side portions of the pair of capacitor parts 500 and the protrusion area P protruding in the Y axis direction.

That is, the coupling part 600b includes the upper coupling member 610 disposed to correspond to the top surface of the upper laminate 510a when coupled to the coupling part 600b and extending in a direction corresponding to the extension directions of the X axis and the Y axis of the upper laminate 510a, the side coupling member 620 extending downward from each of both ends of the upper coupling member 610 in the Y axis direction, and the lower coupling member 630 extending from the side coupling member 620 in the Y axis direction to correspond to the bottom surface of the upper laminate 510a that protrudes from the lower laminate 510b in the Y axis direction. Here, each of the side coupling member 620 and the lower coupling member 630 has a shape in which an area between the pair of capacitor parts 500, i.e., the direction in which the protrusion 410 is disposed is opened.

As described above, the coupling part 600b is coupled to grip the protrusion area P of the electric shock protection part 50.

That is, the upper coupling member 610 is coupled to an upper portion of the capacitor part 500, which corresponds to an upper portion of the protrusion area P of at least the first area A1, the side coupling member 620 is coupled to a side portion of the capacitor part 500, and the lower coupling member 630 is coupled to a lower portion of the capacitor part 500. Also, the upper coupling member 610 is coupled to upper portions of the support part 800 and the ESD protection part, which are an area except for the upper portion of the capacitor part 500 corresponding to the protrusion area P of the first area A1.

Thus, the contact part 300a and the ESD protection part 400 are mechanically coupled to each other by the coupling part 600b.

In the abovementioned sixth exemplary embodiment, the ESD protection part 400 is provided as only the protrusion 410, and the pair of capacitor parts 500 and the ESD protection part 400 are spaced apart from each other.

However, the present disclosure is not limited thereto. For example, like the first modified example of the sixth exemplary embodiment of FIGS. 24 to 26, the ESD protection part 400 further includes the protrusion 410 and the block 420 accommodating the protrusion 410. Here, the inside of the block except for the protrusion 410 may be an empty space. Thus, the coupling part 600b having the coupling function may be applied to the electric shock protection contactor in which the capacitor parts are connected to both sides of the ESD protection part 400. That is, one side surface and the other side surface of the block 420 of the ESD protection part 400 is connected to the capacitor parts 500, respectively.

Here, the pair of capacitor parts 500 may have the alphabet “T” shape in entire outer appearance in the sixth exemplary embodiment as described above.

Also, the ESD protection part 400 may also have the alphabet “T” shape in entire outer appearance. That is, the block 420 of the ESD protection part 400 may have the alphabet “T” shape, and the protrusion 410 may be disposed in the block 420. In more detail, the block 420 has a structure in which an upper block 420a and a lower block 420b are laminated. The upper block 420a extends to further protrude from the lower block 420b in the Y axis direction. Although the block 420 includes the upper block 420a and the lower block 420b, the block 420 may be provided as one body.

Thus, each of the shape in which the above-described capacitor part 500 and the ESD protection part 400 are connected to each other, or the entire shape of the electric shock protection part 50 may have the alphabet “T” shape.

The coupling part 600b is coupled to grip the upper and side portions of the pair of capacitor parts 500, the protrusion area P protruding in the Y axis direction, the upper and side portions of the ESD protection part 400, and the protrusion area P protruding in the Y axis direction.

That is, the upper coupling member 610 of the coupling part 600b is coupled to top surfaces of the pair of capacitor parts 500 and the block 420 of the ESD protection part 400, the side coupling member 620 is coupled to side portions of the pair of capacitor parts 500 and the block 420 of the ESD protection part 400, and the lower coupling member 630 is coupled to bottom surfaces of the pair of capacitor parts 500 and the block 420 of the ESD protection part 400.

In other words, the coupling part 600b is coupled to grip the protrusion area P of the electric shock protection part 50. Here, an edge of the upper coupling member 610 is coupled to a top surface of the protrusion area P, the side coupling member 620 is coupled to a side surface of the protrusion area P, and the lower coupling member 630 is coupled to a bottom surface of the protrusion area P.

In the first modified example of the sixth exemplary embodiment, the ESD protection part provided as the protrusion is applied. However, the present disclosure is not limited thereto. For example, the ESD protection part in accordance with the modified examples of the first exemplary embodiment of (b) to (d) of FIG. 5 and the ESD protection part in accordance with the second exemplary embodiment of (e) and (f) of FIG. 5 may be applied (not shown).

In the fifth and sixth exemplary embodiments, the capacitor part is disposed in the lateral direction of the ESD protection part, or the ESD protection part and the capacitor part are disposed at the same height or on the same plane.

However, the present disclosure is not limited thereto. For example, the coupling part having the coupling function may be applied in the structure in which the ESD protection part and the capacitor part are disposed heights different from each other.

For example, referring to FIGS. 27 to 29, the electric shock protection contactor in accordance with the seventh exemplary embodiment includes a contact part 300a having elasticity, an ESD protection part 400 connected to the lower portion of the contact part 300a to extend from the contact part 300a to the circuit board 20 and including the protrusion 410 made of the conductive material, a pair of support parts 800 disposed on both sides with the ESD protection part 400 therebetween below the contact part 300a, a capacitor part 500 disposed between the ESD protection part 400, the support part 800, and the circuit board 20, and a coupling part 600b coupled to the contact part 300a and the support part 800 to couple the contact part 300a to the ESD protection part 400.

In this embodiment, a constitution including the support part 800, the ESD protection part 400, and the capacitor part 500, which are disposed between the contact part 300a and the circuit board 20 is called an electric shock protection part 50.

The electric shock protection part 50 in accordance with the seventh exemplary embodiment has an alphabet “T” shape with the protrusion area P in the entire shape thereof.

In more detail, the first area A1 includes the support part 800 and the ESD protection part 400, and the second area A2 includes the capacitor part 500. That is, the support part 800 and the ESD protection part 400 are disposed on the first area A1, and the capacitor part 500 is disposed on the second area A2.

Due to the above-described arrangement of the support parts 800, the capacitor parts 500, and the ESD protection part 400, the entire shape of the electric shock protection part 50 when viewed from the outside may have a shape with the protrusion area P, for example, have the “T” shape.

The ESD protection part 400 includes a block 420 and a protrusion 410 and an auxiliary member 430, which are installed to face each other in the block 420. That is, the second and third modified examples of the first exemplary embodiment may be applied to the ESD protection part 400 in accordance with the fifth exemplary embodiment.

The pair of support parts 800 are disposed on both sides of the ESD protection part 400 between the contact part 300a and the capacitor part 500 and connected to the side surface of the ESD protection part 400. Here, the support part 800 is provided in plurality. The plurality of support parts 800 and the ESD protection part 400 are arranged in the extension direction of the contact part 300a and then connected to each other.

Also, a length in the X axis direction in which the plurality of support parts 800 and the ESD protection part 400 are connected to each other is the same as that in the X axis direction of the capacitor part 500, and a length in the Y axis direction in which the plurality of support parts 800 and the ESD protection part 400 are connected to each other is greater than that in the X axis direction of the capacitor part 500. This is done for coupling the coupling part 600b to the support part 800.

Each of the pair of support parts 800 includes an upper laminate 810 extending in one direction and a conductive layer 820 disposed on an outer surface of the upper laminate 810. The upper laminate 810 may be a sheet made of at least one of a dielectric, ceramic, and varistor. The conductive layer 820 may be disposed on at least one of top and side surfaces of the upper laminate and be formed by applying at least one of Ag, Ag/Pd, Cu, Pd, Au, and Al through a printing method.

The capacitor part 500 includes a laminate (hereinafter, referred to as a lower laminate 510), first and second external electrodes 521 and 522 respectively disposed on top and bottom surfaces of the lower laminate 510, first and second internal electrodes 523 and 524 extending to cross the external electrode in the lower laminate 510, and a connection electrode 525 extending in a direction corresponding to the internal electrodes 523 and 524 in the lower laminate 510 and having one end connected to the ESD protection part 400 and the other end connected to an external electrode 522 disposed on a lower surface of the lower laminate 510.

An extension length of the lower laminate of the capacitor part 500 in the X axis direction may correspond to or be the same as that in the X axis direction in which the pair of support parts 800 and the ESD protection part 400 are connected to each other, and an extension length of the capacitor part 500 in the Y axis direction may be less than that in the Y axis direction in which the pair of support parts 800 and the ESD protection part 400 are connected to each other. Thus, the entire outer appearance in which the pair of support parts 800, the ESD protection part 400, and the capacitor part 500 are connected to each other or the entire outer appearance of the electric shock protection part may have an alphabet “T” shape.

In the state in which the pair of support parts 800, the ESD protection part 400, and the capacitor part 500 are connected to each other, each of the support parts further protrudes from the ESD protection part 400 in the Y axis direction, and the protrusion portion of the support part 800 is coupled to the coupling part 600b.

The first and second internal electrodes 523 and 524 are disposed on one side and the other side with respect to the connection electrode 525 in the lower laminate 510.

Also, the first external electrode 521 is disposed on each of one side and the other side of the connection electrode 525 on the top surface of the lower laminate 510 and then connected to the first internal electrode 523.

The second internal electrode 522 is disposed on the bottom surface of the lower laminate 510 and connected to the second internal electrode 524 and the connection electrode 525.

The connection electrode 525 vertically extends in the lower laminate 510 and has one end connected to the auxiliary member 430 of the ESD protection part 400 and the other end connected to the second external electrode 522. Here, an upper end of the connection electrode 525 protrudes to the outside of the lower laminate 510 and is connected to the auxiliary member 530.

In accordance with the capacitor part, a capacitor C is disposed on each of both sides with respect to the connection electrode 525.

The coupling part 600b may grip the upper portion of each of the pair of support parts disposed at the same height and the ESD protection part 400 and the protrusion portion of the support part, which protrudes from the capacitor part in the Y axis direction.

That is, the upper coupling member 610 of the coupling part 600b is coupled to the upper portion of the support part 800, which corresponds to the protrusion area P of at least the first area A1, the side coupling member 620 is coupled to a side portion of the support part 800, and the lower coupling member 630 is coupled to a lower portion of the support part 800. Also, the upper coupling member 610 is coupled to upper portions of the support part 800 and the ESD protection part, which are an area except for the upper portion of the support part 800 corresponding to the protrusion area P of the first area A1.

Thus, the contact part 300a and the ESD protection part 400 are mechanically coupled to each other by the coupling part 600b and the support part 800.

In accordance with the seventh exemplary embodiment, the ESD protection part 400 is disposed at a center above the capacitor part 500.

However, the present disclosure is not limited thereto. For example, the ESD protection part 400 may be disposed to be leaned to one side above the capacitor part 500. In detail, like the modified example of the seventh exemplary embodiment of FIG. 30, the ESD protection part may be disposed out of the center of the upper laminate in the X axis direction, and the connection electrode may be disposed to correspond to the ESD protection part in the lower laminate.

As described above, the electric shock protection contactor 1000 may include the ESD protection part including the protrusion 410 may be disposed between the contact parts 300a and 300b and the circuit board 20, and the protrusion 410 may be disposed to correspond to the ground part of the circuit board 20 to allow the current due to the overvoltage or the ESD voltage of the discharge starting voltage to concentratedly flow through the protrusion, thereby improving the bypassing efficiency to the ground part. Therefore, the current due to the overvoltage or the ESD voltage that is above the discharge starting voltage may be effectively bypassed to prevent the internal circuit from being damaged by the static electricity.

In accordance with the exemplary embodiments, the protection contactor may include the ESD protection part having the protrusion between the contact part and the circuit board, and the protrusion may be disposed at the position corresponding to the ground part of the circuit board to allow the current due to the overvoltage or the ESD voltage of the discharge starting voltage to concentratedly flow through the protrusion, thereby improving the bypassing efficiency. Therefore, the current due to the overvoltage or the ESD voltage that is above the discharge starting voltage may be effectively bypassed to prevent the internal circuit from being damaged by the static electricity.

Although the protection contactor has been described with reference to the specific embodiments, it is not limited thereto. Therefore, it will be readily understood by those skilled in the art that various modifications and changes can be made thereto without departing from the spirit and scope of the present invention defined by the appended claims.

1. A protection contactor comprising:
a contact part coming into contact with a conductor of an electric device and having elasticity; and
an ESD protection part connected to a portion of the contact part to extend to a circuit board disposed to be spaced apart from the contact part and comprising a protrusion made a conductive material;

2. The protection contactor of claim 1, wherein the ESD protection part is disposed to correspond to a ground part of the circuit board.

3. The protection contactor of claim 1, wherein the ESD protection part is disposed between a bottom surface of the contact part and a top surface of the circuit board or disposed at a side of the contact part.

4. The protection contactor of claim 3, further comprising a discharge member connected to the contact part and the circuit board and comprising an ESD protection material.

5. The protection contactor of claim 2, wherein the ESD protection part comprises an auxiliary member disposed below the protrusion to face the protrusion and to be spaced apart from the protrusion and comprising a conductive material.

6. The protection contactor of claim 2, wherein the ESD protection part comprises a block in which at least the protrusion is accommodated.

7. The protection contactor of claim 6, wherein the block has an empty space therein.

8. The protection contactor of claim 6, wherein the block comprises an ESD protection material.

9. The protection contactor of claim 6, further comprising a coating film, to which the ESD protection material is applied, on an outer circumferential surface of the block.

10. The protection contactor of claim 1, further comprising a laminate disposed between the conductor and the circuit board and formed by at least one ceramic sheet.

11. The protection contactor of claim 10, further comprising a capacitor part,
wherein the capacitor part comprises:
first and second external electrodes, which are respectively disposed on an outer surface of the laminate facing the conductor and an outer surface of the laminate facing the circuit board; and
a plurality of internal electrodes extending to cross the first and second external electrodes in the laminate and arranged to be alternately connected to the first and second external electrodes.

12. The protection contactor of claim 10, wherein the laminate is disposed at a side of the ESD protection part and spaced apart from or connected to the ESD protection part, and
the protection contactor further comprises a coupling part configured to couple the laminate and the ESD protection part to the contact part and comprising the conductive material.

13. The protection contactor of claim 12, wherein the coupling part is applied to a lower portion of the contact part as a conductive bonding agent, and the laminate and the ESD protection part are bonded to the contact part by using the conductive bonding agent.

14. The protection contactor of claim 12, wherein the coupling part is coupled to the laminate and the contact part and comprises a coupling member configured to mechanically couple the laminate and the ESD protection part to the contact part.

15.-38. (canceled)
